(19) United States
(12) Patent Application Publication
(10) Pub. No.: US 2025/0386730 A1
(43) Pub. Date: Dec. 18, 2025

(54) ExB Thermoelectric Effect Device

(71) Applicant: LEVY FAMILY TRUST DATED OCTOBER 13, 1997, Irvine, CA (US)

(72) Inventor: George Samuel Levy, Irvine, CA (US)

(73) Assignee: LEVY FAMILY TRUST DATED OCTOBER 13, 1997, Irvine, CA (US)

(21) Appl. No.: 18/861,865

(22) PCT Filed: Apr. 15, 2024
(86) PCT No.: PCT/US2024/024668

§ 371 Date: Oct. 31, 2024

(51) Int. Cl. H10N 10/817; H10N 10/01; H10N 10/853

(52) U.S. Cl. CPC H10N 10/817; H10N 10/01; H10N 10/853

(57) ABSTRACT

The E×B thermoelectric effect is based on the E×B drift, a CPT phenomenon that biases the velocity distribution of charged particles and transports them along cycloids perpendicularly to the E and B fields. This transport mechanism relies on the configuration of the electromagnetic fields, not on phonon drag and temperature difference. The resulting downstream carrier concentration produces a voltage that drives a current through a load. To close the electrical loop, the drift is turned on in the forward channel by increasing mobility and decreasing concentration, and off in the return channel by decreasing mobility and increasing concentration. Power is maximized when the Hall resistivity is matched to the sum of the Drude resistivity of the semiconductor and the equivalent load resistivity. It is also maximized at the thermodynamic threshold, where the mean free path equals the size of the cycloids. This threshold is a powerful design optimization tool.

This invention claims the benefit of U.S. Provisional Application No. 63/464,181 titled, “E×B Drift Thermoelectric Energy Generation Device” filed on May 4, 2023, and which is hereby incorporated by reference. This invention also claims the benefit of U.S. Provisional Application No. 63/588,588 with the same title filed on Oct. 6, 2023, and which is also incorporated by reference. Applicant claims priority pursuant to 35 U.S.C. Par 119(e)(i).

Furthermore, the following publications are thereby incorporated by reference:

U.S. Pat. No. 10,971,669 by G. S. Levy, titled E×B Drift Thermoelectric Energy Generation Device. See reference [1].

An Overview of the E×B Thermoelectric Effect by G. S. Levy MRS Advances, 2023 Springer, DOI 10.1557s43580-023-00521-5. See reference [2].

### FIELD OF THE INVENTION

The present invention relates to thermoelectric devices that rely on the magnetic field, more particularly on the E×B drift to produce a thermoelectric effect, more precisely, the production of electrical energy from heat.

### BACKGROUND

The E×B drift is a well-known, but counterintuitive phenomenon: in the presence of a magnetic field and an electric field perpendicular to each other, electrical carriers move along cycloid paths in the same average direction independently of their charge. The cycloids can be viewed as circles traced at a constant distance around a drifting point called guiding center. The motion of the guiding center determines the direction of the E×B drift. In a collision-less medium (one with infinite mobility), this motion is independent of the carriers' charge or mass, and is perpendicular to both fields.

This invention relies on the E×B drift that occurs in a medium with finite mobility. In contrast, U.S. patent application No. 20180026555 [3] and publication [4] by the same inventor relies on surface drift in a medium with infinite mobility, in which particles follow partial orbits interrupted by the surface. This surface drift occurs in a direction opposite to the cross product of E and B, in other words, in a direction opposite to the E×B drift of this invention. (see the figures and equations 5, 6, 9 and 12 of that application).

This invention is also different from U.S. Pat. No. 10,439,123 [5] and publication [6] by Fu and Skinner which relies on an E×B drift in which particles are transported parallel to the E field (see their FIG. 1 and claims 1, 10 and 19). Their invention is restricted to materials with a band gap energy E_{G} smaller than k_{B}T which results in the saturation (i.e., non-depletion) of the material and a loss in performance. It is also restricted to devices that produce a heat flow in the direction of the E field (see their claims 1, and 19) and are accordingly limited in their configuration to utilize such a heat flow. Fu and Skinner's invention is also restricted to devices that produce an electric field in the direction of the heat flow (their claim 10) and are accordingly limited in their configuration to utilize such an electric field. Their application does not mention the production of any output current or output power.

This invention is also different from US patent with publication number 20180026555 titled Reciprocal Hall Effect Energy Generation Device and from U.S. Pat. No. 10,971,669 titled “E×B drift thermoelectric energy generation device” [1] both by the same inventor, in that this invention teaches design restrictions not mentioned in the previous patent, that maximize the power output.

### SUMMARY

This invention is a device based on the E×B thermoelectric effect, which converts heat into electrical energy. The E×B thermoelectric effect uses the E×B drift, a CPT symmetric transport mechanism that relies on the configuration of electric and magnetic fields. Charged particles in an electric field along the Y axis and a magnetic field along the Z axis, follow cycloidal paths that transport them in the direction of the cross-product of E and B, along the X axis. Unlike the Seebeck effect which requires phonon drag or a temperature difference between a heat source and a heat sink to produce a current, the drift direction and speed is determined by the field configuration. At the microscopic scale, this current can be understood as a bias in the velocity distribution of the particles, caused by the E×B drift. As they produce this current, particles convert their thermal energy to electrical energy, which is replenished by thermal inflow from a heat source.

Accordingly, the E×B thermoelectric effect device uses the E×B drift to convert a heat input to an electrical energy output. The device comprises the following elements:
a) A forward channel oriented along the X axis. This channel has an upstream port and a downstream port in the direction of the E×B drift. It comprises a constituent material that holds electrical carriers in its bulk. The constituent material has the property of high carrier mobility that supports the drift. It allows carriers to follow well-defined and long cycloids uninterrupted by collisions.
b) An electric field, essentially applied along the Y axis perpendicularly to the X axis.
c) A magnetic field, essentially applied along the Z axis perpendicularly to the X and Y axes.

Carried by the drift the carriers produce a current through the forward channel from the upstream port to the downstream port. These ports are connected to a return channel comprising a load, the forward channel and the return channel forming a closed electrical loop.

This invention is notable in that it relies on a field configuration, not on a temperature difference between a heat source and a heat sink to produce a current. Heat from the heat source is converted to electrical energy with no need for a temperature difference or thermal contact with a heat sink.

Unlike other effects, the E×B thermoelectric effect is notable for its reliance on the CPT symmetry of the electromagnetic field. In a medium with infinite mobility, the E×B drift affects electrons and holes equally and their drift velocity and direction are exactly the same and independent of their charges and masses. However, when the medium has a finite mobility, the difference in their transport properties causes the drift to carry electrons and holes in different directions and speeds, thereby breaking time symmetry and allowing CPT symmetry to manifest itself. Even though the charges of the carriers are conserved, their transport properties including mobilities, effective masses and concentrations are different. The asymmetry in the transport properties of the charges (C) produces an asymmetry in their behaviors in parity and time (PT), which results in a bias in the carriers' velocity distribution and in an E×B current.

This velocity distribution asymmetry is accompanied by a bias in the distribution of the relative positions at the beginning and end of a path between collisions. This positional bias can be quantified by the cycloidal shape of the paths. These cycloids can be seen as circular cyclotron orbits whose centers move with the drift velocity. The average radius of these orbits can be understood as a measure of this behavioral asymmetry and is called asymmetry measure r. Alternatively, the average diameter of an orbit can also be considered as a measure of asymmetry. For the purpose of simplicity, the following discussion uses the radius as a measure of asymmetry.

This asymmetry becomes significant when its size r is at the scale of the average path length λ, of the particles. The term “average path length” refers to a generalization of the mean free path as shall be explained. When the asymmetry is much larger than the average path length or equivalently, when the ratio r/λ called the thermodynamic threshold is much larger than one, the asymmetry disappears, paths become quasi linear, the velocity and position distribution of carriers becomes unbiased and there is no significant thermoelectric effect. Conversely, when the asymmetry is much smaller than the average path length, and r/λ approaches zero, the thermoelectric effect does occur, but its operation is very inefficient because the carrier density is too low, thermal flow is restricted by the low carrier concentration, and the high magnetic field may be unrealizable.

Accordingly, to maximize the E×B thermoelectric effect, the asymmetry measure r, and the average path length λ should approximately be equal, or, equivalently, the thermodynamic threshold r/λ should be about equal to one. Since r and λ are both functions of design parameters, equating them (or setting the thermodynamic threshold r/λ=1) provides a powerful tool for deriving optimum values for these parameters for the purpose of maximizing the power output. Design parameters include: 1) the physical characteristics of the forward channel such as its constituent material, doping, temperature, and the mobility and the concentration of the carriers; 2) its environment such as the magnitude and direction of the applied electric field, the magnitude and direction of the applied magnetic field; and 3) its design geometry such as the thickness and length of the forward channel including the position of the upstream and downstream ports.

In summary:
1) The E×B thermoelectric effect device has design parameters.
2) Carriers have an average path length λ which is a function of these design parameters.
3) Carriers follow cycloidal paths which have an average size r called asymmetry measure. It is defined by the dimension of a cyclotron orbit of the carriers in the magnetic field, and is also a function of these design parameters.
a) The ratio r/λ is optimum when it is equal to one. (In practice, accounting for design tradeoffs, material data inaccuracy and fabrication tolerance, this ratio can range from 0.1 to 10.
4) Setting the ratio r/λ at or near its optimum value determines the optimum design parameters.

Two concepts, the “equivalent mean free path,” and the “average path length” are introduced in this invention for the purpose of combining limitations in the length of the paths contributed by different processes in the E×B device. The goal is to express these limitations in a manner that allows them to be added, compared, and combined in the manner of resistances or conductances connected in series or parallel.

The “equivalent mean free path,” applies to dissipative effects caused by collisions incurred by carriers at several locations as they travel around the electrical loop. These locations comprise the bulk of the forward channel, the surfaces bordering the forward channel, the return channel, and the load.

The mean free paths at these locations are proportional to the conductance of the location. i.e., λ=(m*v/nq²)σ where m* is the effective mass, v is the thermal velocity of the carriers, n is their concentration, q is their charge, and the conductivity of the material is σ=(L/A) C, where L is the length of the conductor, A is its cross-sectional area, and C is the conductance.

For the purpose of selecting optimum design parameters, it is helpful to “match” the mean free paths around the loop just as one matches load and source conductances. However, unlike conductances, these mean free paths cannot be added in a harmonic sum because the constant of proportionality (m*v/nq²)(L/A) between mean free path and conductance, changes around the loop. Note that in this invention the term “harmonic sum” refers to the reciprocal of a sum of reciprocals. For example, conductances in series add up as a harmonic sum.

Therefore, the concept of equivalent mean free path has been created to allows the mean free path information to be conveniently added together as a harmonic sum just like conductances. For example, the equivalent load mean free path of the load is equal to the mean free path in the forward channel multiplied by the ratio of the conductance C_{Load} of the load to the Drude conductance C_{Drude} of the forward channel. i.e., λ_{Load}=λ_{Bulk}C_{Load}/C_{Drude} or equivalently in terms of resistance, λ_{Load}=λ_{Drude}R_{Drude}/R_{Load}.

Similarly, the equivalent resistivity and mobility for the load can be defined respectively as ρ_{Loud}=ρ_{Drude}R_{Load}/R_{Drude} and μ_{Load}=μ_{Drude}R_{Drude}/R_{Loud}.

Accordingly, all dissipative effects contribute to the combined equivalent mean free path as the harmonic sum of individual equivalent mean free paths (in the load, bulk, and surfaces of the forward channel) i.e., 1/λ_{Loop}=1/λ_{Load}+1/λ_{Surfaces}+1/λ_{Bulk}.

These definitions provide a convenient tool for maximizing the power output: matching the equivalent mean free paths is equivalent to matching resistances or conductances. They also have the benefit of simplifying the mathematical formulas describing the optimization of the E×B thermoelectric effect.

Equating the combined equivalent mean free path λ to the asymmetry measure r one can show that maximum power output can be achieved when the product of mobility and the magnetic field μ_{Drude} B_{z}=2 and that μ_{Bulk} B_{z}=4 and μ_{Surfaces}B_{z}=4.

Furthermore, maximum power output is also obtained using a generalized source/load resistance matching involving the Drude resistance and the Hall resistance of the device, and the Drude resistance of the load as follows:
1) The Hall resistance of the forward channel should be matched to the sum of Drude resistance of the forward channel (including the bulk and surfaces), and the Drude resistance of the return channel including the load. This is a new design paradigm taught by this invention.
2) The Drude resistance of the forward channel should be matched to the Drude resistance of the return path and load in combination. (i.e., their sum). This is the well-known source/load matching requirement.

The second concept, the average path length, expresses limitations to the length of the paths that cannot be combined as harmonic sums but must be independently equated to the asymmetry measure to maximize power. These limitations are of two kinds: 1) dissipative, and 2) non-dissipative. Thus, the average path length for dissipative limitations is the combined equivalent mean free path discussed above. The average path length for non-dissipative limitations include the isothermal scale height, the thickness of the depletion zone, and other design constraints:
1) the isothermal scale height: the average path length of the carriers should be made equal to the isothermal scale height caused by the electric field and the temperature of forward channel.
2) the depletion zone: the average path length of the carriers should be made equal to the thickness of the depletion zone caused by the electric field, the doping, and the carrier concentration in the forward channel.

The isothermal scale height represents a statistical limit of how high up the electric potential energy gradient a carrier can travel. It is the decay constant of the carriers' density distribution which decreases exponentially with elevation, due to the potential energy gradient caused by the electric field as a function of temperature. Equating the asymmetry measure to the average path length and to the isothermal scale height allows one to derive the optimal values for the electric field and the temperature.

The thickness of the depletion zone is a necessary design limit that restricts the range of motion of the carriers. The thickness of the depletion zone is a function of the electric field and of the carrier concentration (and doping) and should be neither too large nor too small. A forward channel thicker (in the direction of the electric field, i.e., the Y axis) than the depletion zone, includes a region devoid of electric field. This region does not support the drift but allows conventional Ohmic conduction which detrimentally shorts out the E×B effect in the rest of the device. Conversely, a forward path thinner than the depletion zone unduly restricts the E×B flow. Therefore, the depletion zone can be considered as a restriction to the average path length. Equating the asymmetry measure to the average path length and to the thickness of the depletion zone allows one to derive optimal values for the carrier concentration and doping level.

Therefore, two novel aspects of this invention include:
1) The equivalent mean free path is used to combine mean free paths due to diffusive processes (e.g., collisions) in different interconnected materials or systems. A combined equivalent mean free path is obtained by adding individual mean free paths in a harmonic sum, just like conductances in series are added, and they can be matched for the purpose of maximizing power. Therefore, the combined equivalent mean free path is the harmonic sum of all equivalent mean free paths in a circuit and must be matched in combination to the asymmetry measure to maximize power.
2) The average path lengths represent any limitation to path lengths that must be independently matched (not as a harmonic sum) to the asymmetry measure to maximize power. They include the combined equivalent mean free path discussed above (which is already a harmonic sum,) as well as other limitations due non-diffusive effects which must also be independently matched to the asymmetry measure. These non-diffusive effects include the isothermal scale height, the thickness of the depletion zone, and design requirements.

In summary, the design parameters should be selected such that the average path length of the carriers is essentially equal to the combined equivalent mean free path, the combined equivalent mean free path being a harmonic sum of the equivalent mean free path in the bulk, the surface equivalent mean free path at the surfaces, and the load equivalent mean free path in the load.

Furthermore, the design parameters should be selected such that the average path length of the carriers is essentially equal to the isothermal scale height of the carriers caused by the electric field and the temperature of the forward channel.

In addition, the design parameters should be selected such that the average path length of the carriers is essentially equal to the thickness of the depletion zone caused by the electric field, the doping, and the carrier concentration of the carriers in the forward channel.

The ratio of the asymmetry measure to the average path length defines the thermodynamic threshold, which should optimally be equal to one. This limitation is based on having perfectly accurate data such as mobility, concentration, the magnitudes of the magnetic fields and the electric fields. In practice, this is never the case, and one must allow some tolerance in accuracy. Furthermore, design trade-offs may have to be made. Therefore, a range for the thermodynamic threshold ratio between 0.1 and 10 may be acceptable. A narrower range between 0.3 and 3 is better. A yet narrower range between 0.5 and 2.0 is better and an even narrower range between 0.9 and 1.1 is even better. Each of these ranges can be applied independently to 1) the combined limitations due to dissipative interaction; 2) the isothermal scale height; and 3) the thickness of the depletion zone.

In general, carriers in the forward channel can be of two kinds: negatively charged (i.e., electrons) and positively charged (i.e., holes). In a medium with infinite mobility, the drift is notable in that the carriers drift in the same general direction independently of their charges.

Therefore, when both electrons and holes are present, electrons make negative contributions to the current, and holes make positive contributions. These contributions add up subtractively. When these particles have the same concentration and mobilities, the net current is zero. Therefore, to maximize the net output current, one should maximize the imbalance between their contributions: The forward channel properties should be selected to make negative and positive contributions unequal in magnitude, resulting in the current being non-zero. This can be done by selecting design properties such as constituent material and doping, as well as the properties of electrons and holes including effective masses, mobilities and concentrations. For example, one can increase the contribution from electrons and decrease that of holes, by selecting a material where electrons have a higher mobility and higher concentration than holes.

Under realistic operating conditions, that is, when a load is inserted in the circuit, and the forward channel has a finite mobility, the actual E×B drift is deflected away from the X axis by two mechanisms. The first is due to the voltage across the device produced by the current through the load. This voltage generates an electrical field component in the device along the X axis that deflects the primary electrical field E_{y} away from the Y axis. The redirection of the electrical field causes a redirection of the drift away from the X axis down toward the bottom surface.

The second mechanism is due to the collisions of carriers in the bulk of the material. This mechanism is diffusive in nature and adds a component to the drift, down the electrical potential energy gradient. These two mechanisms operating in combination in the bulk and at the top surface of the semiconductor, cause carriers to move along a diagonal direction between the Y axis and the X axis down toward the bottom surface. An additional repulsion force (e.g., Lennard-Jones potential) present at the bottom surface redirects the carriers to move along the X axis.

The material comprising the forward channel can be a semiconductor with high mobility such as, but not limited to, InAs or InSb. It can also comprise other high mobility materials such as but not limited to InAsₓSb₁₋ₓ or alloys of In, As, Sb and Ga in a combination appropriately chosen to operate at a desired temperature. The material can also comprise graphene, (for example doped graphene on Silicon Carbide [7]) or graphite or any such materials with high mobility.

The material in the forward channel can also consist of a superconductor with the proviso that the forward channel cannot have a dimension along the Z axis that exceeds the penetration depth of the magnetic field, and a dimension along the Y axis that exceeds the penetration depth of the electric field. Clearly, dimensions larger than these penetration depths would result in the expulsion of these fields from the bulk of the superconductor and produce regions in the forward channel incapable of supporting the drift, but capable of supporting Ohmic conduction that would short out the device.

For the E×B thermoelectric effect to drive a current around a circuit successfully, the E×B drift should not operate uniformly in the same spatial direction. This can be done with a return channel incapable of supporting the E×B drift because of its low mobility, but capable of supporting Ohmic conduction. In general, the forward channel should have high mobility and low concentration to support the drift, and the return channel, low mobility, and high concentration to maintain Ohmic conduction while not supporting the drift. This can be achieved with a semiconductor such as InAs, InSb or doped graphene in the forward channel and a metal conductor such as Cu in the return channel. The load is any device that uses electrical energy such as but not limited to a resistor, a capacitor, an inductor, and a rechargeable battery.

Alternatively, one can insert in parallel or in series with the primary forward channel, secondary forward channels each one contributing additively their respective current or voltage applied to the load.

E×B devices can be assembled in many different electrical configurations. For example, the forward channels can be electrically connected in series, or in parallel through their upstream and downstream ports forming a closed circuit with the load.

E×B devices can be assembled in many different geometrical configurations such as stacks in which the electric fields applied to the forward channels are aligned in parallel. This configuration has the benefit of simplifying the source of the electric field. For example, two insulated capacitor plates can provide an electric field to multiple E×B devices inserted between the plates.

Conversely, E×B devices can also be stacked such that the electrical fields applied to the stack layers are antiparallel. For example, a single insulated plate can operate as a capacitive cathode or anode when inserted in a stack between two layers of devices.

Furthermore, a single magnetic source, for example, a permanent magnet, can provide a magnetic field to multiple devices, all devices using the same magnetic field in parallel.

The electric field can be produced by electrets, ferroelectrics, doped surfaces, or junctions. It can also be produced by capacitor plates charged by an external voltage source. Alternatively, it can be produced by capacitor plates charged by the electrical energy output of the device.

The E×B device can give rise to a Peltier effect if a significant work function is present at the junctions between the forward and return channels. A junction where carriers experience a rise in potential energy gets colder; the other junction where the carriers go down the potential energy gradient gets hotter. This thermal effect can be maximized by shorting the current in the return path.

Conversely, if there is a temperature difference between the junctions caused by the presence of a work function, the performance of the E×B thermoelectric effect as an electricity generator can be improved by thermally shorting the hot and cold junctions.

An object of this invention is to teach a method of selecting design parameters for optimizing the performance of an E×B thermoelectric device. These parameters include the selection of a constituent material for the forward channel, the doping level of the material, the temperature of operation, the electric field, the magnetic field, the mobility and concentration of the carriers, the dimension of the forward channel including its thickness and length, and the resistance of the load. This method includes:
a) Expressing the asymmetry measure r caused by the magnetic field in terms of the above design parameters.
b) Expressing the average path length/in terms of these design parameters.
c) Equating the expressed asymmetry measure to the expressed average path length.
d) Solving for the design parameters.
e) Fabricating the E×B thermoelectric effect device according to the solved design parameters.

Fully tuned to the thermodynamic threshold, an InAs device operating 24/7, using ambient heat at 300K, running at 250K, with a magnetic field of 1.07T, can produce up to 1337 mW/mm² or as much as 3967 time the Shockley-Queisser solar cell limit of 0.337 mW/mm².

Being an electromagnetic phenomenon, the E×B thermoelectric effect is CPT symmetric as exemplified by the electromagnetic right-hand rule. It achieves its extraordinary power generation efficiency because it falls outside the framework of applicability of the H-Theorems proven by Boltzmann [8], Tolman [9], Gibbs [10], and von Neumann [11]. As shown by Levy [2,3,4], these proofs cover time symmetrical systems. They do not apply to CPT symmetrical phenomena such as the E×B thermoelectric effect, capable of breaking time symmetry.

Another object of this invention is to convert thermal energy drawn from a heat source to electricity without the need for a heat sink.

Another object of this invention is to achieve a thermoelectric effect without the need for a temperature difference between a heat source and a heat sink.

Yet, another object of this invention is to produce electrical energy by converting heat from the environment at ambient temperature, for example at or lower than 300K, without the need for any other source of energy such as combustion, solar, wind, geothermal or hydroelectricity.

### BRIEF DESCRIPTION OF THE DRAWINGS

FIG. 1. The E×B drift. Particles drift in the direction of the cross product of E and B with a direction and velocity independent of their mass and charge.

FIG. 1A. shows that when the mobilities and concentrations of holes and electrons are not equal, their contributions to the drift current do not cancel out.

FIG. 2 shows the basic physical configuration that includes an electric field produced by insulated capacitor plates, electrets, ferroelectrics or a junction, and a magnetic field generated by magnets or electromagnets.

FIG. 3. A device implementing the E×B thermoelectric effect includes a forward channel where the drift is enabled by high mobility and low concentration, and a return channel where the drift is disabled by low mobility and high concentration. The forward channel supports the drift in one direction, and the return channel which includes a load (e.g., a resistance or a rechargeable battery,) supports Ohmic transport. Alternatively, the return channel could include a multiplicity of forward channels all oriented with the same polarity such that drift occurs in the same circular direction i.e., clockwise, or counterclockwise.

FIG. 4. is a diagram showing the electric field vectors for the E×B drift. The drift is deflected by angle θ_{E×B} from the X axis by two mechanisms: 1) a voltage across the device produced by the current flowing through the load ρ_{Load}, which rotates the applied electrical field by angle θ_{Load}, and 2) collisions due to the Drude resistivity ρ_{Drude} caused by collisions in the bulk of the semiconductor and with its surfaces, which further deflect the drift by θ_{Drude}. The figure assumes a Hall resistivity ρ_{Hall}=1 to make the current vectors commensurate with the field vectors.

FIG. 4A is a diagram for the current vectors corresponding to the field vectors in FIG. 4.

FIG. 5 is a vector diagram for the optimum electric field for the E×B drift. Maximum power to the load is achieved when the Hall figure of merit and the Drude figure of merit are both equal to 1, or equivalently, when ρ_{Hall}=ρ_{Drude}+ρ_{Load} and ρ_{Load}=ρ_{Drude}.

FIG. 5A is a diagram for the optimum current vectors corresponding to the optimum field vectors in FIG. 5.

FIG. 6 shows the power output as a function of Hall/Drude resistivity matching. The Hall power factor F_{Hall} reaches the maximum 1 when the Hall figure of merit f_{Hall}=1. This corresponds to the Hall matching condition ρ_{Hall}=ρ_{Drude}+ρ_{Load}. It also corresponds to operating at the thermodynamic threshold r=λ. When f_{Hall}>1, the system approaches the thermodynamic limit where the cycloid segments become too short to sustain the E×B drift. When f_{Hall}<1, collisions become rare resulting in poor thermal coupling between carriers and the semiconductor material, and a decrease in the thermoelectric power output.

FIG. 6A shows the power output as a function of Drude/Drude resistivity matching. The Drude power factor F_{Drude} reaches the maximum 1 when the Drude figure of merit f_{Drude}=1. This corresponds to the well-known Drude load matching condition, ρ_{Load}=ρ_{Drude}.

FIG. 7. illustrates the E×B drift above the thermodynamic threshold when r/λ>>1, particles follow quasi-linear paths and there is no E×B drift.

FIG. 7A. illustrates the E×B drift below the thermodynamic threshold when r/λ<<1 and the E×B drift is inefficient because of wasted space, poor thermal flow, and low particle concentration.

FIG. 7B. illustrates the E×B drift at the thermodynamic threshold when r/λ=1 and the power output is maximum.

FIG. 8. This is an exploded view of the proposed device. An E×B device comprises a semiconductor in a sandwich between two insulated capacitor plates. The magnetic field can be produced by a permanent magnet not shown in the figure.

FIG. 9. This is a graph that illustrates the magnetic field requirement as a function of temperature for several materials. Indium Arsenide operates well near or slightly below room temperature with a magnetic field around 1 Tesla, which is easily achieved with a permanent magnet.

FIG. 10. This is a graph showing the power output for several materials as a function of the magnetic field. InAs operates well with a magnetic field of about 1 Tesla, easily produced by a permanent magnet.

FIG. 11. This is a graph of the power output as a function of temperature for InAs. InAs operates well between 225K and 300K. At 250K, an InAs device can produce up to 1337 mW/mm² or as much as 3967 time the Shockley-Queisser solar cell limit of 0.337 mW/mm².

FIG. 12 This figure shows simulation frames (a) through (d) as time-lapse images of an E×B simulation of negatively charged particles in a chamber. Width=2 microns; Length=2 microns; E=328000V/m pointing upward; B_{z}=IT “into the paper”; T=300K; mobility=∞; and effective mass=0.023. Red trajectories represent particles moving right, and blue ones moving left, up, or down. (a) The particles begin at randomly distributed positions (b) are carried by the E×B drift toward the left wall, (c) accumulate on the left wall, (d) dribble down the left wall and accumulate on the floor in the bottom left corner.

FIG. 13 This figure shows the end result of the simulation shown in FIG. 12 The particles accumulate on one side of the simulation chamber.

FIG. 14 This figure shows a simulation of the drift of negatively charged particles at different scales in a medium with finite mobility. The particles start out randomly distributed in a box and drift diagonally down and to the left with a drifting angle of 26.57 degrees from the horizontal, as predicted by the theory. T=300K, E=328V/m upward and B_{z}==1 Tesla “into the paper,” and μ=2. (a) Number of particles=10. The box is 0.5 microns×0.25 micron. (b) Number of particles=20. The box is 2 microns×1 micron. (c) Number of particles=20. The box is 10 microns×5 microns. (d) Number of particles=100. The box is 100 microns×50 microns.

FIG. 15 shows a stack configuration in which the electric field is produced by insulated capacitor plates inserted between the semiconductor layers.

FIG. 16 shows a stack configuration in which the electric field is produced by electrets inserted between the semiconductor layers.

FIG. 17 shows a stack configuration in which the electric field is produced when both top and bottom surfaces of the semiconductor layers are doped.

FIG. 18 shows a stack configuration in which the electric field is produced when only one of the surfaces of the semiconductor layers is doped.

FIG. 19 shows a reticulated doped surface which has an anisotropic electrical conductivity, low along the X direction.

FIG. 20 illustrates a stack configuration in which capacitor plates are shared between stack layers and the contact points are positioned along the X axis.

FIG. 21 illustrates a stack configuration in which capacitor plates are shared between stack layers and the contact points are positioned along an axis antidiagonal to the drift.

FIG. 22 illustrates a stack configuration in which capacitor plates are shared between stack layers and the contact points are positioned on the bottom surface of the semiconductor.

FIG. 23 illustrates a multistage configuration in which the beginning and end stages generate the voltage required to charge the capacitor plates. The voltage in this version is self-sustaining.

### DETAILED DESCRIPTION

### 1. Introduction

This invention teaches an E×B thermoelectric device optimized for maximum power output. It specifies design parameters such as, but not limited to, the best semiconductor material, its doping and carrier concentration, the magnitude of the electric and magnetic field and the dimensions of the device. For convenience, the reader can refer to a summary of optimizing design equations in Appendix A.

The E×B thermoelectric effect and the E×B drift are two related but different phenomena. To understand the first, one must be familiar with the second. A reader unfamiliar with the E×B drift, can find a clear, concise, and accurate description in [12]. An in-depth explanation is provided in [13].

The E×B drift is a CPT symmetric transport mechanism for charged particles in electrical and magnetic fields. It is well-known in plasma physics but can also apply to carriers in high mobility semiconductors and superconductors.

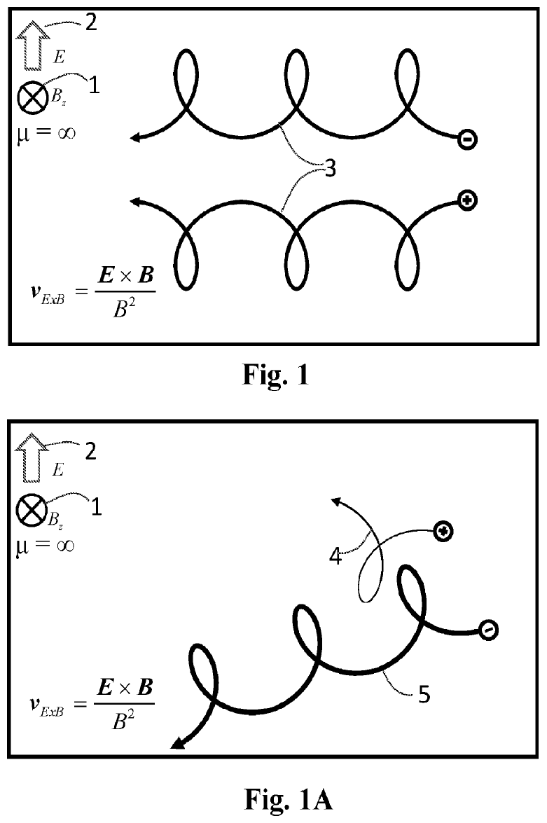

Charged particles in a magnetic field B_{z} along the Z axis, follow circular orbits in the XY plane. As shown in FIG. 1, an electric field E_{y} 2 along the Y axis added perpendicularly to B_{z} 1, changes the shape of their orbits from circles to cycloids 3: particles decelerate going up the electrical potential energy gradient, and accelerate going down. The radius of curvature of the orbits becomes greater at the bottom than at the top, converting circles to cycloids, thereby causing particles to drift in the direction of the cross-product E×B, perpendicular to E_{y} and B_{z}.

In a medium with infinite mobility, the drift velocity v_{E×B} is independent of the charge or mass of the particles and is given by:

$${v}_{E \times B} = \frac{{E}_{y}}{{B}_{z}} \qquad ( 1 )$$

When mobility is infinite as shown in FIG. 1, the E×B drift affects electrons and holes equally and their drift velocity and direction are exactly the same, independently of their charges and masses. Therefore, when their concentrations are equal, their contributions to the overall current cancel out and the net output current is zero. However, as shown in FIG. 1A, when the mobility and concentrations of holes 4 and electrons 5 are not equal, their contributions to the drift current do not cancel out.

The E×B drift is a manifestation of the Hall effect for which the Hall resistivity is defined as

$${ρ}_{Hall} = \frac{{B}_{z}}{nq} \qquad ( 2 )$$

where n is the particle density, and q is the charge. Using equation (1), one can show that the E×B current density J_{E×B}=nqv_{E×B} is actually the Hall current density:

$${J}_{E \times B} = {J}_{Hall} = \frac{{E}_{y}}{{ρ}_{Hall}} \qquad ( 3 )$$

In this sense, the E×B drift is the inverse of the Hall effect. The first uses E_{y} and B_{z} as inputs, and generate J_{E×B} as output, the second uses J_{Hall} and B_{z} as inputs, and generate E_{y} as output.

The mobility of carriers must be high enough but not necessarily infinite. To support the E×B drift, mobility must be high enough to allow carriers to follow cycloidal paths mostly uninterrupted by collisions. It cannot occur in a low mobility medium in which paths are quasi-linear and short in comparison with a cyclotron's orbit.

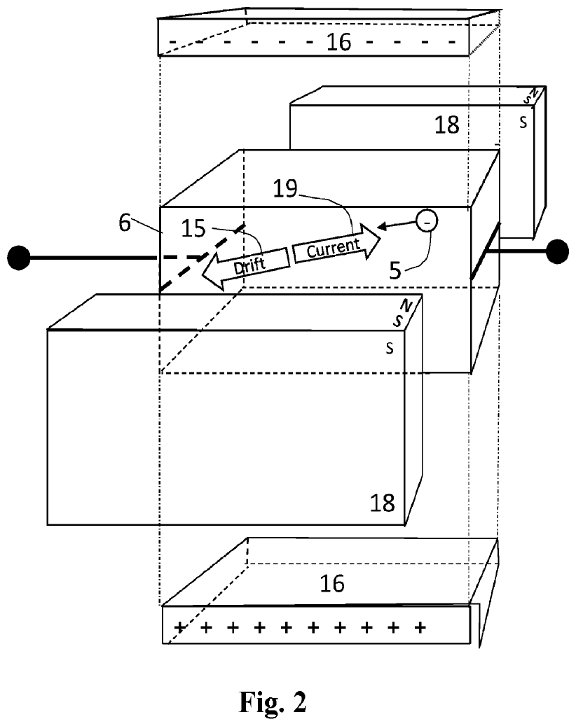

FIG. 2 shows how an electric field can be produced across a semiconductor layer 6 by insulated capacitor plates, electrets, ferroelectrics, or doped surfaces 16, The figure also shows how a magnetic field can be produced by magnets or electromagnets 18. The direction of the drift 15 depends on the direction of the fields, the mobility, and the effective mass of the carriers 5. The output current 19 flows in a direction opposite to the drift 15 if the charge of the carriers is negative.

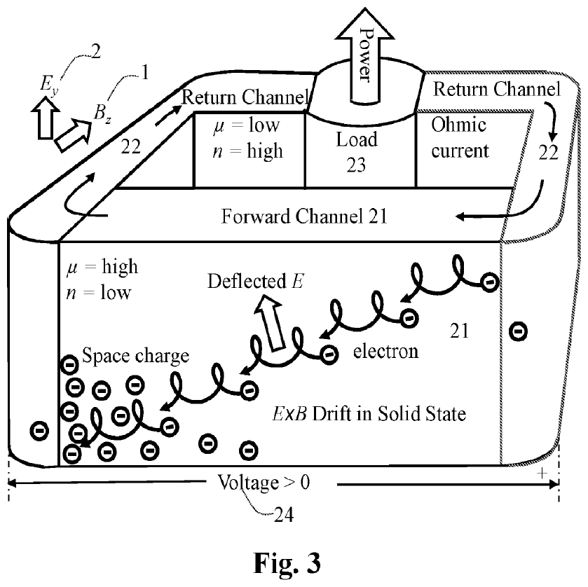

As shown in FIG. 3, the E×B thermoelectric effect requires the following components:
1) An electric field E_{y} 2 along the Y axis and a magnetic field B_{z} 1 along the Z axis which enables the E×B drift essentially along the X axis.
2) A forward channel 21 with an upstream port and a downstream port essentially along the X axis, and comprising a medium favorable to the drift, with a high carrier mobility and low carrier concentration which allows long paths and the formation of cycloids. For example, the forward channel could comprise a high mobility semiconductor such as InAs.
3) A return channel 22 along the X axis connected to the ports of the forward channel and forming a closed circuit with the load. A return channel, taken for granted in conventional thermoelectrics, is made explicit in this invention to clearly show that the energy generated by the forward channel is utilized. In a first version shown in FIG. 3, the return channel 22 could be specifically designed not to support the drift, yet still allow carriers to circulate. Such a return channel should have a low carrier mobility to truncate paths to quasi-linear segments and prevent the formation of cycloids, but a high carrier concentration to enable Ohmic conduction. For example, it could comprise a metal with relatively low mobility and high concentration such as Cu. The circuits comprising the return channel can be as simple as lead connections to the load. In a second version, the return channel comprises a rechargeable battery capable of storing the electrical potential energy produced by the forward channel. In a third version, the forward channel could be just the first of a multiplicity of connected forward channels, each with its own set of X, Y and Z axes, and with their own perpendicular electric and magnetic fields, all the channels making their contributions to the load current with the same polarity, in the same circular direction, either clockwise or counterclockwise.

The following topics shall be covered:
The E×B drift in a medium with finite mobility and with a load.
Equivalent load resistivity.
Thermodynamic threshold optimization.
E×B optimizing calculator.
Simulation of E×B Device.
Construction of Device.

### 2. The E×B Drift in a Medium with Finite Mobility and with a Load

Under idealized conditions of infinite mobility and zero load, the E×B drift occurs along the X axis as described by equations (1) and (3). However, under realistic conditions, two processes deflect the drift down away from the X axis as shown in FIGS. 1A, 2 and 3.

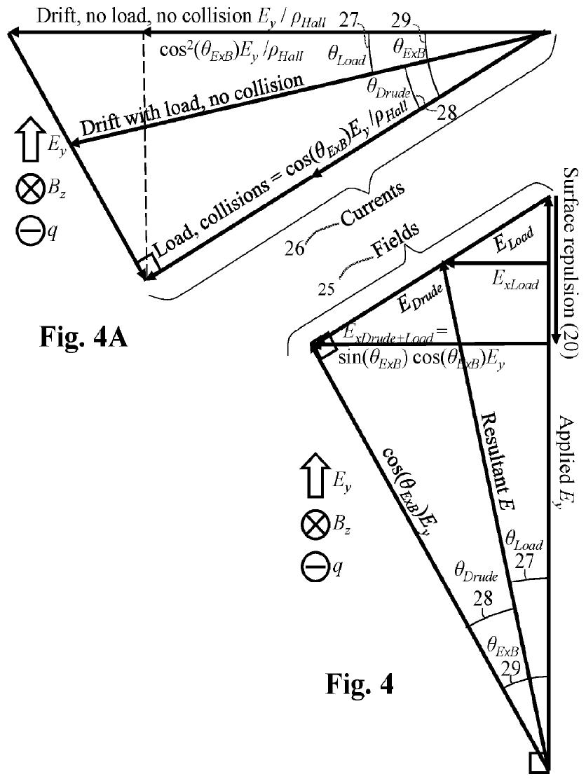

FIGS. 4 and 4A use a vector diagram to illustrate these two mechanisms. FIG. 4 shows the field vectors 25 across the load and the device, and FIG. 4A the current vectors 26. The figures assume a Hall resistivity ρ_{Hall}=1 to make the current vectors commensurate with the field vectors. These two mechanisms include:
1) A voltage 24 across the device shown in FIG. 3 due to the current flowing through the load ρ_{Load}. This voltage adds an X component E_{xLoad} to the primary electric field E_{y}. In addition, the surface adds a surface repulsion Y component 20, for example in the form of Lennard-Jones potential. At the surface, these two components deflect the electrical field by angle θ_{Load}, 27 resulting in a redirection of the drift, away from the X axis by the same angle down toward the bottom surface.
2) Collisions in the bulk and with surfaces of the forward channel due to the Drude resistivity ρ_{Drude}=ρ_{Bulk}+ρ_{Surfaces} in the semiconductor. These collisions truncate the cycloids and further deflect the drift by angle θ_{Drude}, 28 down toward the bottom surface. (In the limit of low mobility and high concentration, the drift is replaced by Ohmic diffusion as particles dribble down their potential energy gradient along the Y axis.)

These two mechanisms, in combination, rotate the E×B drift by an angle 29 θ_{E×B}=θ_{Drude}+θ_{Load} away from the X axis.

As illustrated in FIGS. 1A, 2 and 3, carriers move diagonally down. As the carriers reach the surface they keep on drifting because they do not remain at the bottom. Collisions with the floor impart to them an isothermal distribution that decreases with height exponentially according to a decay constant called the isothermal scale height. Collisions raise carriers above the surface and allow them to continue their drift in the X direction. In other words, at the bottom surface, the repulsion force (e.g., Lennard-Jones potential) redirects the drift along the X axis.

In analogy to sailboat tacking, the bottom surface redirects the drift from its diagonal direction to point along the X axis. As the carriers accumulate downstream, they produce a voltage V 24. As they drift on the bottom surface against this voltage, they convert some of their kinetic energy into potential energy W=qV. Since the carriers are in isothermal contact with the surface, they absorb thermal energy Q=W=qV from the surface to restore their kinetic energy. In addition, their flow in the forward channel narrows down their position uncertainty to the downstream section of the channel. Correspondingly, this surface drift is negentropic such that ΔS=−Q.

Carriers begin their cycle in the forward channel where the E×B drift is redirected along the X axis and powered by the surface thermal energy. As they enter the return channel and traverse the load 23, they move from a high potential to a low potential region, transferring energy to the load:

$$W = qV \qquad ( 4 )$$

As the carriers diffuse through the load their positional uncertainty returns to its original value (they could be located on either side of the load) resulting in an increase in entropy ΔS=Q=W. Overall, the device converts heat to electrical energy with no net change in its own entropy and this heat. is replenished from a heat bath without the need for a heat sink. The drift purely due to the field configuration and not caused by phonon drag or a temperature difference as in the Seebeck effect. Therefore, no temperature difference between a heat source and a heat sink is required to drive this current.

Even though thermal exchanges do occur at the floor of the forward channel it also does occur in its ceiling because the mean free path has the same order of magnitude as the separation between the bottom and top surfaces, Furthermore, thermal exchanges also occur in the bulk of the semiconductor, as in reality no material has infinite mobility that precludes any collision. In fact, infinite mobility is detrimental even in the forward channel because collisions are essential for replenishing heat converted to electrical energy and for powering the drift. However, too low a mobility is also undesirable because some mobility is needed to form cycloids. This invention introduces the principle of thermodynamic threshold as a means for striking a balance between these two extremes and as a criterion for calculating design parameters that optimize the performance of an E×B thermoelectric device. The following topics shall be covered:
The E×B drift in a medium with finite mobility and with a load.
Thermodynamic threshold optimization.
E×B optimizing calculator.
Simulation of E×B device.
Construction of device

### 3. Equivalent Load Resistivity

The concept of equivalent load resistivity is introduced as a simple means for maximizing the power output by matching the equivalent resistivities of the load to the resistivity of the E×B device. The equivalent load resistivity is defined as ρ_{Load}=ρ_{Device}R_{Load}/R_{Device}. Matching the resistance of the load R_{Load} to that of the device R_{Device} is equivalent to matching their equivalent resistivities ρ_{Load} and ρ_{Device}.

$$( {ρ}_{Load} ≡ {R}_{Load} \frac{{ρ}_{Device}}{{R}_{Device}} and {R}_{Load} = {R}_{Device} ) \to ( {ρ}_{Load} = {ρ}_{Device} ) \qquad ( 5 )$$

Similarly, the concepts of equivalent mean free path and equivalent mobility are introduced as λ_{Load}=λ_{Device}R_{Device}/R_{Load} and μ_{Load}=μ_{Device}R_{Device}/R_{Load}, respectively. These generalizations of resistivity, mean free path and mobility have the benefit of simplifying mathematical formulas and the optimization of the E×B thermoelectric effect.

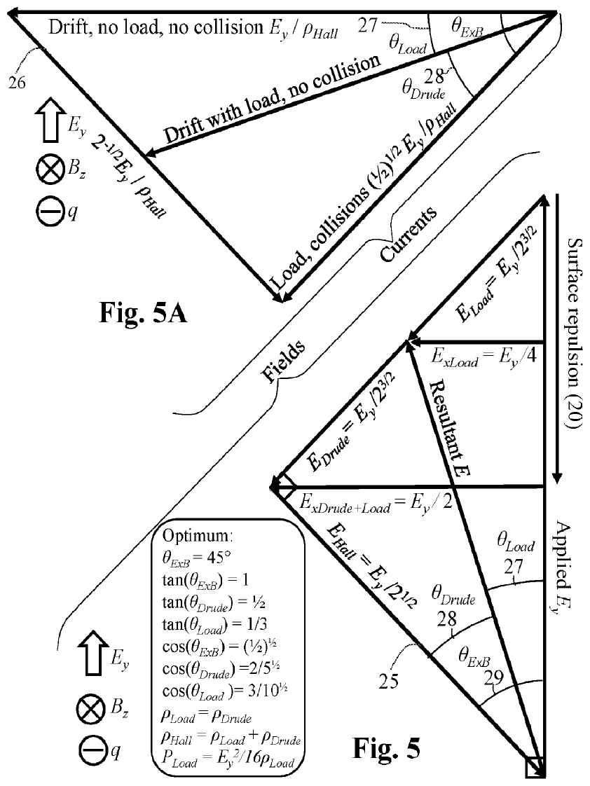

FIGS. 5 and 5A show that maximum power to the load is achieved when ρ_{Hall}=ρ_{Drude}+ρ_{Load} and ρ_{Load}=ρ_{Drude}.

As proven in Appendix B, for an arbitrary ρ_{Hall}, ρ_{Drude}, and ρ_{Load} the drift slope is:

$$tan ( {θ}_{E \times B} ) = \frac{{ρ}_{Drude} + {ρ}_{Load}}{{ρ}_{Hall}} \qquad ( 6 )$$

Note that in the ideal case of infinite mobility and no load, i.e., ρ_{Drude}+ρ_{Load}=0, the deflection θ_{E×B} from the X axis is zero. Conversely, when there is no magnetic field and no Hall effect, i.e., ρ_{Hall}=0, particles drift down their electrical potential energy gradient with a slope of 90°. Since ρ_{Drude}=1/nqμ_{Drude} and ρ_{Hall}=B_{z}/nq, equation (6) can be rewritten as:

$$tan ( {θ}_{E \times B} ) = \frac{1 + nq {μ}_{Drude} {ρ}_{Load}}{{μ}_{Drude} {B}_{z}} \qquad ( 7 )$$

As shown in FIG. 5, the field corresponding to the source voltage that drives the drift along the X axis is:

$${E}_{xDrude + Load} = sin ( {θ}_{E \times B} ) cos ( {θ}_{E \times B} ) {E}_{y} \qquad ( 8 )$$

Multiplying by ρ_{Load}/(ρ_{Drude}+ρ_{Load}) produces the field across the equivalent load resistivity:

$${E}_{xLoad} = sin ( {θ}_{E \times B} ) cos ( {θ}_{E \times B} ) \frac{{ρ}_{Load}}{{ρ}_{Drude} + {ρ}_{Load}} {E}_{y} \qquad ( 9 )$$

Dividing by ρ_{Load} yields the current density through the load:

$${J}_{Load} = sin ( {θ}_{E \times B} ) cos ( {θ}_{E \times B} ) \frac{1}{{ρ}_{Drude} + {ρ}_{Load}} {E}_{y} \qquad ( 10 )$$

The product E_{xLoad}J_{Load} is the power transmitted to the load:

$${P}_{Load} = {sin}^{2} ( {θ}_{E \times B} ) {cos}^{2} ( {θ}_{E \times B} ) \frac{{ρ}_{Load}}{{( {ρ}_{Drude} + {ρ}_{Load} )}^{2}} {E}_{y}^{2} \qquad ( 11 )$$

Expressing the sine and cosine in terms of ρ_{Drude}+ρ_{Load} using equation (6) and rearranging yields:

$${P}_{Load} = \frac{{( \frac{{ρ}_{Drude} + {ρ}_{Load}}{{ρ}_{Hall}} )}^{2}}{{( 1 + {( \frac{{ρ}_{Drude} + {ρ}_{Load}}{{ρ}_{Hall}} )}^{2} )}^{2}} \frac{( \frac{{ρ}_{Load}}{{ρ}_{Drude}} )}{{( 1 + \frac{{ρ}_{Load}}{{ρ}_{Drude}} )}^{2}} \frac{{E}_{y}^{2}}{{ρ}_{Drude}} \qquad ( 12 )$$

The foregoing analysis can be simplified by grouping terms in equation (12). The first two fractional terms represent unnormalized power maximization factors. The first one is the Hall power factor that shall be designated as F_{Hall}, and the second, the Drude power factor, as F_{Drude}. Accordingly, equation (12) can then be rewritten with the normalized power factors as:

$${P}_{Load} = {F}_{Hall} {F}_{Drude} \frac{{E}_{y}^{2}}{16 {ρ}_{Drude}} \qquad ( 13 )$$

The factors F_{Hall} and F_{Drude} can be expressed in term of dimensionless figures of merit f_{Hall} and f_{Drude} respectively:

$${F}_{Drude} = \frac{4 {f}_{Drude}}{{( 1 + {f}_{Drude} )}^{2}} where {f}_{Drude} = \frac{{ρ}_{Load}}{{ρ}_{Drude}} \qquad ( 14 )$$

$$and$$

$${F}_{Hall} = \frac{4 {f}_{Hall}^{2}}{{( 1 + {f}_{Hall}^{2} )}^{2}} where {f}_{Hall} = \frac{{ρ}_{Drude} + {ρ}_{Load}}{{ρ}_{Hall}} \qquad ( 15 )$$

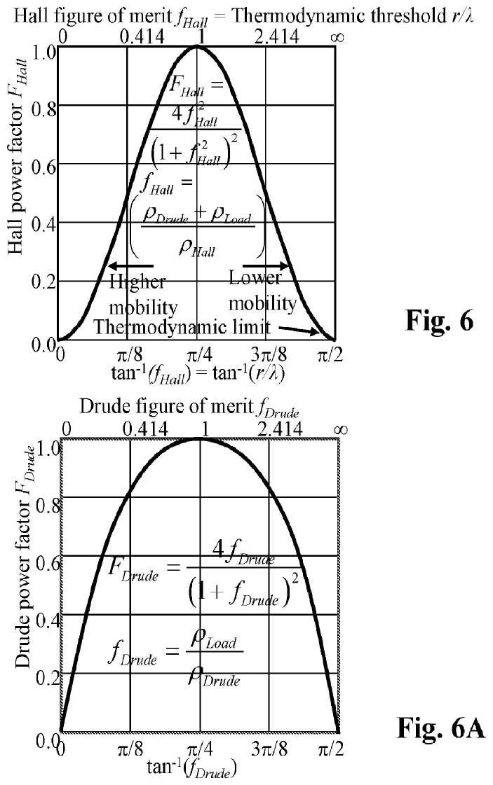

FIGS. 6 and 6A illustrate the effect of the figures of merits on the power maximization factors. FIG. 6 shows that the Hall power factor F_{Hall} reaches the maximum 1 when the Hall figure of merit f_{Hall}=1. This corresponds to the Hall matching condition ρ_{Hall}=ρ_{Drude}+ρ_{Load}. It also corresponds to operating at the thermodynamic threshold r=λ. When f_{Hall}>>1, the system approaches the thermodynamic limit where the cycloid segments become too short to sustain the E×B drift. When f_{Hall}<<1, collisions become rare resulting in poor thermal coupling between carriers and the semiconductor material, and a decrease in the thermoelectric power output. FIG. 6A shows that the Drude power factor F_{Drude} reaches the maximum 1 when the Drude figure of merit f_{Drude}=1. This corresponds to the well-known Drude source/load matching condition, ρ_{Load}=ρ_{Drude}.

Note that since f_{Hall}=(ρ_{Drude}+ρ_{Load})/ρ_{Hall}, f_{Hall} is also equal to the slope of the drift tan(θ_{E×B}) according to equation (6).

$${f}_{Hall} = \frac{{ρ}_{Drude} + {ρ}_{Load}}{{ρ}_{Hall}} = tan ( {θ}_{E \times B} ) \qquad ( 16 )$$

The well-known load matching criterion can now be generalized to combine the Drude and Hall resistivities. Equation (14) indicates that output power is maximized when the equivalent load resistivity is matched to the source Drude resistivity:

$${f}_{Drude} = 1 ; {F}_{Drude} = 1 ; and {ρ}_{Load} = {ρ}_{Drude} \qquad ( 17 )$$

Similarly, equation (15) shows that output power is also maximized when:

$${f}_{Hall} = 1 ; {F}_{Hall} = 1 ; {ρ}_{Hall} = {ρ}_{Drude} + {ρ}_{Load} \qquad ( 18 )$$

and the drift slope angle is given by:

$${θ}_{E \times B} = π / 4 \qquad ( 19 )$$

Since ρ_{Hall}=B_{z}/nq and ρ_{Drude}=1/nqμ_{Drude}, f_{Hall} can be also expressed in terms of the mobility and the magnetic field as:

$${f}_{Hall} = \frac{1 + nq {μ}_{Drude} {ρ}_{Load}}{{μ}_{Drude} {B}_{𝓏}} \qquad ( 20 )$$

Under the Drude matched load condition, (ρ_{Load}=ρ_{Drude}=1/nqμ_{Drude}), f_{Hall} becomes:

$${f}_{Hall} = \frac{2}{{μ}_{Drude} {B}_{𝓏}} \qquad ( 21 )$$

Furthermore, combining the Hall matched load condition, f_{Hall}=1 with equation (21), produces the optimum combination of mobility and magnetic field:

$${μ}_{Drude} {B}_{𝓏} = 2 \qquad ( 22 )$$

Applying the optimum drift angle θ_{E×B}=π/4 and the Drude load matching condition ρ_{Drude}=ρ_{Load} to equations (9) and (10) yields the optimal load voltage and the load current density:

$${E}_{xLoad} = \frac{1}{4} {E}_{y} \qquad ( 23 )$$

$${J}_{Load} = \frac{1}{4} \frac{{E}_{y}}{{ρ}_{Load}} = \frac{1}{4} \frac{{E}_{y}}{{ρ}_{Drude}} \qquad ( 24 )$$

Using equations (23) and (24), and the definition ρ_{Drude}=1/nqμ_{Drude}, the maximum power that can be sent to the load is:

$${P}_{LoadMax} = \frac{1}{16} \frac{{E}_{y}^{2}}{{ρ}_{Drude}} = \frac{{E}_{y}^{2}}{{ρ}_{Load}} or {P}_{LoadMax} = \frac{1}{16} nq {μ}_{Drude} {E}_{y}^{2} \qquad ( 25 )$$

This section concludes with equation (25) which shows that under both Drude and Hall load matching conditions, the output power is proportional to n, μ_{Drude} and E_{y}².

However, this equation does not specify optimum values for these quantities. In fact, increasing them beyond a certain point may be counterproductive. For example, a high carrier concentration n can produce space charges that cancel the electric field, thereby stopping the E×B drift. A very high mobility μ_{Drude} can lead to reduced thermal contact between the carriers and the semiconductor, resulting in a lower power output. A high electric field E_{y} can put the semiconductor in deep depletion mode thereby pinching off the current through the device.

The next section addresses these issues and provides a methodology for selecting n, μ_{Drude} and E_{y} as well as specifying optimal dimensions for the device. It includes a microscale analysis that introduces the thermodynamic threshold ratio r/λ in which the radius r of a cycloid is a measure of the asymmetry generated by the E×B drift and λ is the average path length. It will be shown that for maximum power, r/λ must satisfy the same requirement as f_{Hall} as expressed in equations (18) and 21):

$$\frac{r}{λ} = {f}_{Hall} = \frac{2}{{μ}_{Drude} {B}_{𝓏}} = 1 \qquad ( 26 )$$

### 4. Thermodynamic Threshold Optimization

The analysis in this section is classical, which is justified for the following reason. Even though the energy distribution of carriers in a semiconductor is non-classical, the only carriers involved in thermal interaction and in the E×B drift are the “unfrozen” ones which reside above the Fermi level. These particles form a distinct subset with their own Maxwellian distribution, and therefore, they can be treated classically.

The thermodynamic threshold provides a design guideline for maximizing the power output. It is a concept related to the thermodynamic limit [14], a consequence of the central limit theorem. The thermodynamic limit refers to the operation of a system when its volume V, and number of particles N are both taken to infinity such that the concentration n remains fixed i.e. V→∞. N→∞, with n=N/V. In the limit, microscopic fluctuations are averaged out by the large number of particles. The thermodynamic limit can be stated as:

$$N = Vn \to ∞ \qquad ( 27 )$$

In a gas where λ is the average path length and σ is the collision cross section, the particle concentration is given by:

$$n = \frac{1}{λ σ} \qquad ( 28 )$$

Therefore, the thermodynamic limit can be expressed as a dimensionless quantity:

$$\frac{( V / σ )}{λ} \to ∞ \qquad ( 29 )$$

When a physical asymmetry is present, its size r defines the scale V/σ. For example, the asymmetry r of the E×B drift can be defined by the dimension of its cycloids which is quantified by the radius of cyclotron orbit. In this case, the thermodynamic limit is expressed by replacing V/σ by r:

$$\frac{r}{λ} \to ∞ \qquad ( 30 )$$

Accordingly, the thermodynamic threshold τ is defined for the E×B drift as the ratio of r to λ:

$$τ = \frac{r}{λ} \qquad ( 31 )$$

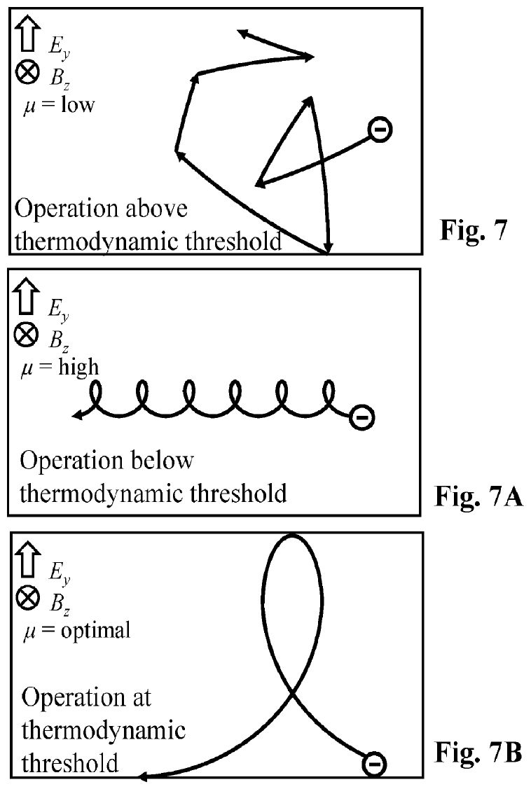

When τ is much larger than one, the system approaches the thermodynamic limit. As shown in FIG. 7, paths become quasi linear, cycloids are truncated, and the asymmetry is nullified leading to a cancellation of the drift and a lower power output. In contrast, as illustrated in FIG. 7A. when τ is much smaller than one, the asymmetry is pronounced, cycloids are fully formed, but the low concentration, reduced thermal flow, and wasted space also reduces the power output. Maximum power occurs at the thermodynamic threshold as shown in FIG. 7B when the threshold function is unity, and the size or measure of the asymmetry matches the mean free path r=λ. Since r and λ are both functions of design parameters, equating them is a powerful tool for optimizing these parameters to operate at the thermodynamic threshold for maximum power output.

This designing method includes:
Determining the dimensions of the asymmetry. Since a cycloid is a drifting cyclotron orbit, the radius of this orbit can be taken as a measure of this asymmetry.
Expressing each component of the average path length in terms of design parameters such as the magnetic field B_{z}, the electric field E_{y}, the carrier concentration n, the carriers' mobility in the bulk μ_{Bulk}, the operating temperature T, and dimensions δₓ, δ_{y}, and δ_{z} of the semiconductor.
Equating the dimensions of the asymmetry to the components of the average path length.
Solving for the design parameters.
Fabricating the device in accordance with the design parameters.

The sections below cover the following topics:
Dimensions of the asymmetry channel.
Using the average path length to calculate design parameters.
The E×B drift in a superconductor.
Maximum output power.

### 4.1 Dimensions of the Asymmetry Channel

The size or measure of the E×B asymmetry is equal to the size of a cycloid, which is quantified by the radius of a cyclotron orbit in the XY plane:

$${r}_{xy} = \frac{{mv}_{xy}}{{qB}_{𝓏}} \qquad ( 32 )$$

where m is the effective mass and q is the charge of the particles. The velocity V_{xy} in the XY plane can be expressed as a function of temperature:

$${v}_{xy} = \sqrt{\frac{2 {k}_{B} T}{m}} \qquad ( 33 )$$

The size or measure of the asymmetry is:

$${r}_{xy} = \frac{1}{{qB}_{𝓏}} \sqrt{2 {mk}_{B} T} \qquad ( 34 )$$

In an actual device, the voltage across the load or the device produces an electric field component along the X axis, which rotates the primary field away from the Y axis by angle θ_{Load}, which in turn, rotates the E×B drift and the size r_{xy} of the asymmetry by the same angle. To apply the thermodynamic threshold correctly, r_{xy} should be projected on the Y axis. This is done by multiplying equation (34) by cos(θ_{Load}) as shown in FIGS. 4, 4A, 5 and 5A:

$${r}_{y} = cos ( {θ}_{Load} ) \frac{1}{{qB}_{𝓏}} \sqrt{2 {mk}_{B} T} \qquad ( 35 )$$

### 4.2 Using the Average Path Length to Calculate Design Parameters

Several mechanisms contribute to limiting the average path length. Some are dissipative such as collisions that carriers experience at several locations around the circuit. These locations comprise the bulk of the forward channel, the surfaces bordering the forward channel, the return channel, and the load. Dissipative contributions to the average path length add up in combination as a harmonic sum. Equating this sum to the asymmetry measure generates optimal design parameters.

The other mechanisms are non-dissipative. They include 1) the isothermal scale height due to the electric field, which limits how high carriers can travel, and 2) the thickness of the depletion zone which is a design requirement on the electric field and the carrier concentration to maintain the device in depletion mode. Non-dissipative contributions to the average path length are equated independently to the asymmetry measure to derive optimal design parameters.

First, let us consider the dissipative phenomena which are Drude-resistive. Assume a semiconductor layer with a bulk mobility μ_{Bulk}, and a thickness δ_{y} along the Y axis separating surfaces. Let the contribution to the mean free path caused by collisions in the bulk of the semiconductor be λ_{yBulk}, and the contribution due to collisions with the top and bottom surfaces be λ_{surfaces} such that λ_{Surfaces}=δ_{y}. The combined Drude contributions projected on the Y axis due to the bulk and the surfaces is the harmonic sum of λ_{yBulk}, and λ_{Surfaces}:

$$\frac{1}{{λ}_{yDrud}} = \frac{1}{{λ}_{yBulk}} + \frac{1}{{λ}_{Surfaces}} \qquad ( 36 )$$

and the corresponding equivalent mobilities are:

$$\frac{1}{{μ}_{Drude}} = \frac{1}{{μ}_{Bulk}} + \frac{1}{{μ}_{Surfaces}} \qquad ( 37 )$$

Combining the above with the equivalent mean free path λ_{Load} from the load yields the combined dissipative contributions:

$$\frac{1}{{λ}_{yDrud + Load}} = \frac{1}{{λ}_{yDrud}} + \frac{1}{{λ}_{Load}} = \frac{1}{{λ}_{yBulk}} + \frac{1}{{λ}_{Surfaces}} + \frac{1}{{λ}_{Load}} \qquad ( 38 )$$

The corresponding mobilities assuming an equivalent load mobility are:

$$\frac{1}{{μ}_{Drude + Load}} = \frac{1}{{μ}_{Drude}} + \frac{1}{{μ}_{Load}} = \frac{1}{{μ}_{Bulk}} + \frac{1}{{μ}_{Surfaces}} + \frac{1}{{μ}_{Load}} \qquad ( 39 )$$

These contributions are design dependent. Optimizing their values to maximize the power output determines design parameters such as the material property μ_{Bulk}, the semiconductor thickness δ_{y}, and the load resistance R_{Load}.

To maximize the power output, one can match the load resistance to the device resistance or equivalently match their equivalent mean free paths and mobilities. This yields:

$$2 {λ}_{yDrud + Load} = {λ}_{yDrud} = {λ}_{Load} and 2 {μ}_{Drude + Load} = {μ}_{Drude} = {μ}_{Load} \qquad ( 40 )$$

The Drude mobility μ_{Drude} can be broken down into components as it is the harmonic sum of the bulk mobility μ_{Bulk} and the surface mobility μ_{Surfaces} as per equation (37). Optimizing the contribution of the bulk and that of the surface to the overall Drude resistivity of the forward channel can be done with the ad-hoc approximation of making these contributions equal. This is justified by linear programming according to which the maximum combined mobility is reached when all contributions are equal. (If they were not, one could always increase mobility by moving them closer together). Therefore, we can set:

$${μ}_{Bulk} = {μ}_{Surfaces} and {λ}_{yBulk} = {λ}_{Surfaces} \qquad ( 41 )$$

Combining equations (38), (39), (40) and (41) yields:

$${μ}_{Drude + Load} = \frac{1}{2} {μ}_{Load} = \frac{1}{2} {μ}_{Drude} = \frac{1}{4} {μ}_{Bulk} = \frac{1}{4} {μ}_{Surfaces} and \qquad ( 42 )$$

$${λ}_{y} = \frac{1}{2} {λ}_{Load} = \frac{1}{2} {λ}_{yDrud} = \frac{1}{4} {λ}_{yBulk} = \frac{1}{4} {λ}_{Surfaces}$$

where λ_{y} is the equivalent mean free path from all combined contributions, projected on the Y axis.

The non-dissipative contributions to the mean free path can now be considered. They include a ceiling λₕ imposed by the isothermal scale height due to the E_{y} field and above which carriers cannot go; and a limit λ_{D}, a design requirement on the thickness of the depletion zone, and beyond which the E×B drift ceases to operate because there is no E_{y} field.

These quantities can also be optimized by equating them with each other and with the size or measure of the asymmetry. Using equation (42), the mean free path λ_{y} and mobility μ_{Drude} due to the dissipative processes are equal to the non-dissipative contributions:

$${μ}_{Drude + Load} = \frac{1}{2} {μ}_{Load} = \frac{1}{2} {μ}_{Drude} = \frac{1}{4} {μ}_{Bulk} = \frac{1}{4} {μ}_{Surfaces} = {μ}_{h} = {μ}_{D} and \qquad ( 43 )$$

$${λ}_{y} = \frac{1}{2} {λ}_{Load} = \frac{1}{2} {λ}_{yDrud} = \frac{1}{4} {λ}_{yBulk} = \frac{1}{4} {λ}_{Surfaces} = λ , = {λ}_{D}$$

At the thermodynamic threshold τ=1, and r_{y}=λ_{y} as per equation (31). Combining this information with equation (43) yields:

$${r}_{y} = {λ}_{y} = \frac{1}{2} {λ}_{Load} = \frac{1}{2} {λ}_{yDrud} = \frac{1}{4} {λ}_{yBulk} = \frac{1}{4} {λ}_{δ} = {λ}_{h} = {λ}_{D} \qquad ( 44 )$$

Each contribution to the mean free path shall now be discussed for the purpose of deriving optimal design parameters:
1) Contribution due to collisions in the bulk.
2) Contribution due to surfaces.
3) Contribution due to the isothermal scale height.
4) Contribution due to the depletion zone.

### 4.2.1 Contribution Due to Collisions in the Bulk

The component of the mean free path λ_{xyBulk} relevant to the E×B drift is in the XY plane of the cycloids, and it is equal to the product of the mean velocity v_{xy} projected on the XY plane times the mean free time in the bulk t_{Bulk}:

$${λ}_{xyBulk} = {v}_{xy} {t}_{Bulk} \qquad ( 45 )$$

For an effective mass m, and a charge q, mobility in the bulk of the material is [15]:

$${μ}_{Bulk} = \frac{q}{m} {t}_{Bulk} \qquad ( 46 )$$

Using this definition of mobility, equations (45) can be stated as:

$${λ}_{xyBulk} = \frac{{mv}_{xy}}{q} {μ}_{Bulk} \qquad ( 47 )$$

Since v_{xy} is given by:

$${v}_{xy} = \sqrt{\frac{2 {k}_{B} T}{m}} \qquad ( 48 )$$

the mean free path in equation (47) can be written as:

$${λ}_{xyBulk} = \frac{{μ}_{Bulk}}{q} \sqrt{2 {mk}_{B} T} \qquad ( 49 )$$

The relevant component of λ_{xyBulk} with respect to the thermodynamic threshold is its projection on Y axis which is done as shown in FIG. 5, by multiplying equation (49) by cos(θ_{Load}):

$${λ}_{yBulk} = cos ( {θ}_{Load} ) \frac{{μ}_{Bulk}}{q} \sqrt{2 {mk}_{B} T} \qquad ( 50 )$$

Since λ_{yBulk}=4λ_{y} as per equation (44), the above equation can be rewritten as:

$${λ}_{y} = cos ( {θ}_{Load} ) \frac{{μ}_{Bulk}}{4 q} \sqrt{2 m {k}_{B} T} \qquad ( 51 )$$

Dividing equation (35) by equation (51) and with equation (43) yields the thermodynamic threshold ratio as a function of mobility and the magnetic field:

$$τ = \frac{{r}_{y}}{{λ}_{y}} = \frac{2}{{μ}_{Drude} {B}_{z}} = \frac{4}{{μ}_{Bulk} {B}_{z}} \qquad ( 52 )$$

At the thermodynamic limit when τ=1 and r_{y}=λ_{y} as per equation (44), the optimum magnetic field is given by:

$${B}_{z} = \frac{4}{{μ}_{Bulk}} \qquad ( 53 )$$

and from equation (35) and (53) the optimum width of the asymmetry projected on the Y axis is:

$${r}_{y} = cos ( {θ}_{Load} ) \frac{{μ}_{Bulk}}{4 q} \sqrt{2 m {k}_{B} T} \qquad ( 54 )$$

From FIG. 5 the optimal value for cos(θ_{Load})=3/10^{1/2}. Therefore, the above equation becomes:

$${r}_{y} = \frac{3}{\sqrt{10}} \frac{{μ}_{Bulk}}{4 q} \sqrt{2 m {k}_{B} T} \qquad ( 55 )$$

Note the similarity between equation (21) and equation (52) which mutually confirms their validity. These equations were independently derived. The first uses the Hall load matching condition (f_{H}=1), and the second, the thermodynamic threshold (τ=1). In combination they state:

$${f}_{Hall} = τ = \frac{{r}_{y}}{{λ}_{y}} = \frac{2}{{μ}_{D rude} {B}_{z}} = \frac{4}{{μ}_{Bulk} {B}_{z}} \qquad ( 56 )$$

FIGS. 6 and 6B can be seen as a graphical representation of the thermodynamic threshold. Power peaks when f_{Hall}=τ=1 and when f_{Drude}=1.

### 4.2.2 Contribution Due to Surfaces

Collisions with the surfaces bordering the channels also contribute to the mean free path. Since the orbits are in the XY plane, the only dimensions of main relevance are the height δ_{y} of the forward channel and its length δₓ. Its depth, δ_{z}, which is parallel to the B_{z} field should not be so narrow as to interfere with cycloids, (i.e., δ_{z}=δ_{y}) but can be made arbitrarily large (i.e., δ_{z}>>δ_{y}) at the convenience of the designer to maximize the total output current.

Since cycloidal orbits are interrupted by surfaces, the Y component of the mean free path contributed by surfaces is determined by the separation between the bottom and top surfaces δ_{y}:

$${λ}_{Surfaces} = {δ}_{γ} \qquad ( 57 )$$

The optimality condition r_{y}=λ_{y}=λ_{Surfaces}/4 in equation (44) and the optimum value for r_{y} in equation (54) yields the optimum height of the semiconductor forward channel:

$${δ}_{y} = cos ( {θ}_{Load} ) \frac{{μ}_{Bulk}}{q} \sqrt{2 m {k}_{B} T} \qquad ( 58 )$$

The cosine for the optimal θ_{Load} is 3/10^{1/2} as illustrated in FIG. 5. Therefore, the above equation can be expressed as:

$${δ}_{y} = \frac{3}{\sqrt{10}} \frac{{μ}_{Bulk}}{q} \sqrt{2 m {k}_{B} T} \qquad ( 59 )$$

Similarly, the X component of the mean free path contributed by surfaces is determined by the separation between the left and right surfaces δₓ. Hence:

$${δ}_{x} = \frac{3}{\sqrt{10}} \frac{{μ}_{Bulk}}{q} \sqrt{2 m {k}_{B} T} \qquad ( 60 )$$

and, as shown in FIG. 5, the optimal drifting angle is θ_{E×B}=45° down from the X axis.

### 4.2.3 Contribution Due to the Isothermal Scale Height

Collisions in the bulk and with surfaces equalize the carriers' temperature across the device. Their density distribution ρ(y) is isothermal, decreasing exponentially with height y due to the vertical E_{y} field:

$$ρ ( y ) = {ρ}_{0} {e}^{- \frac{y}{{h}_{y}}} \qquad ( 61 )$$

where h_{y} is conventionally known as the isothermal scale height, which is defined as:

$$h = \frac{{k}_{B} T}{q E} \qquad ( 62 )$$

The exponential distribution in equation (61) applies to particles as well as to their paths. In other words, long paths that carry the particle high above the bottom surface are less likely than short paths. Approximating the exponential function as a square function, one can view the isothermal scale height as a ceiling that limits the size of the paths. This limiting process is non-dissipative as it only requires the electric field and would be present even in the absence of collisions.

The electric field is deflected from E_{y} to E. (i.e., E=E_{y} cos(θ_{E×B})/cos(θ_{Drude})) by the voltage produced by the load as shown in FIG. 5. The scale height h which is also deflected because it is in the direction of the field must be projected back on the Y axis by the same angle. In other words:

$$E = {E}_{y} \frac{cos ( {θ}_{E \times B} )}{cos ( {θ}_{Drude} )} and h = {h}_{y} \frac{cos ( {θ}_{Drude} )}{cos ( {θ}_{E \times B} )} \qquad ( 63 )$$

Substituting equations (63) into equation (62) results in the cancellation of the cosine terms:

$${h}_{y} = \frac{{k}_{B} T}{{qE}_{y}} \qquad ( 64 )$$

Therefore, the contribution to the mean free path projected on the Y axis due to the scale height is:

$${λ}_{f} = {h}_{y} = \frac{{k}_{B} T}{{qE}_{y}} \qquad ( 65 )$$

This non-dissipative contribution to the average path length is equated independently to the asymmetry measure to derive optimal design information. The optimality condition r_{y}=λ_{y}=λₕ in equation (44) and the optimum value for r_{y} in equation (54) yields the optimal electric field:

$${E}_{y} = \frac{2}{cos ( {θ}_{L o o d} )} \frac{1}{{μ}_{Bulk}} \sqrt{\frac{2 {k}_{B} T}{m}} \qquad ( 66 )$$

Using the optimal cos(θ_{Load})=3/10^{1/2} from FIG. 5, the above equation becomes:

$${E}_{y} = \frac{2 \sqrt{10}}{3} \frac{1}{{μ}_{B u l k}} \sqrt{\frac{2 {k}_{B} T}{m}} \qquad ( 67 )$$

The field produced by the load across the device is obtained using equation (23) and (67)

$${E}_{xLood} = \frac{\sqrt{10}}{6} \frac{1}{{μ}_{B u l k}} \sqrt{\frac{2 {k}_{B} T}{m}} \qquad ( ) ( 68 )$$

Since the voltage across the load is the same as across the device, V_{Load}=E_{xLoad}δₓ. Therefore, using equations (68) and (60), the voltage across the load is:

$${V}_{Load} = \frac{{k}_{B} T}{q} \qquad ( 69 )$$

### 4.2.4 Contribution by Depletion Zone

When the particle concentration n is sufficiently low, the semiconductor is in full depletion mode. Carriers cannot produce space charges large enough to significantly affect the electric field, E_{y}. However, a low value of n is detrimental because it leads to a low output current and power.

Increasing n can increase the power output up to a point of diminishing return. A large n leads to the formation of a space charge that cancels the E_{y} field, takes the semiconductor out of depletion mode, and stops the E×B drift. Without an electric field across the whole height (along the Y axis) of the semiconductor, some of the particles are carried, not by the drift, but by an Ohmic current flowing in the direction opposite to the drift, which short circuits the device.

The carrier concentration n should be neither too high, nor too low. It must be low enough to keep the semiconductor in depletion mode across its whole thickness thereby maintaining the E_{y} field. However, it should not be so low as to put the semiconductor in a starvation mode with not enough carriers to produce power.

The carrier concentration and the electric field can be adjusted to keep the semiconductor on the verge of being out of depletion mode across its whole thickness. In this state, the electric field and the carrier concentration decrease in tandem with elevation, neither one overcoming the other, both always present, allowing the E×B drift to operate across the whole semiconductor. The thickness of the depletion zone can be derived from Gauss's law: the total charge per unit area nqD required to cancel the electric field E and produce a depletion zone of thickness D is equal to εE. i.e., nqD=εE. Hence the thickness of the depletion zone is:

$$D = \frac{ε E}{n q} \qquad ( 70 )$$

where ε is the permittivity of the material.

As shown in FIG. 5, the voltage produced by the load across the device redirects the electrical field from E_{y} to E. i.e., E=E_{y} cos(θ_{E×B})/cos(θ_{Drude}). The resulting depletion zone has a thickness along the E field given by:

$$D = \frac{cos ( {θ}_{E \times B} )}{cos ( {θ}_{Drude} )} \frac{ε {E}_{y}}{nq} \qquad ( 71 )$$

However, the D vector in this equation points along the E field. For the depletion zone to correctly contribute to the mean free path, the D vector must be projected onto the Y axis, i.e., D=D_{y} cos(θ_{Drude})/cos(θ_{E×B}). Substituting this information into equation (71) yields the projection of D on the Y axis:

$${D}_{y} = \frac{{cos}^{2} ( {θ}_{E \times B} )}{{cos}^{2} ( {θ}_{D r u d e} )} \frac{ε {E}_{y}}{nq} \qquad ( 72 )$$

Applying the optimal E_{y} in equation (66), to equation (72) produces the thickness for the depletion zone projected on the Y axis:

$${D}_{y} = \frac{2 {cos}^{2} ( {θ}_{E \times B} )}{{cos}^{2} ( {θ}_{Drude} ) cos ( {θ}_{Load} )} \frac{ε}{nq {μ}_{B u l k}} \sqrt{\frac{2 {k}_{B} T}{m}} \qquad ( 73 )$$

This non-dissipative contribution to the average path length is equated independently to the asymmetry measure to derive optimal design information. The size of the depletion zone defines the size of the mean free path along the Y axis D_{y}=λ_{D}. Now, applying the optimality condition r_{y}=λ_{y}=λ_{D} in equation (44) and the optimum value for r_{y} in equation (54) to the above equation yields the carrier concentration:

$$n = \frac{8 {cos}^{2} ( {θ}_{E \times B} )}{{cos}^{2} ( {θ}_{Drude} ) {cos}^{2} ( {θ}_{Load} )} \frac{ε}{m {μ}_{B u l k}^{2}} \qquad ( 74 )$$

From FIG. 5, optimality requires that cos²(θ_{E×B})=1/2, cos²(θ_{Drude})=4/5, and cos²(θ_{Load})=9/10. Therefore, the optimal value of n is obtained by rewriting equation (74) as:

$$n = \frac{50}{9} \frac{ε}{m {μ}_{B u l k}^{2}} \qquad ( 75 )$$

Note that n is the optimum concentration, which in practice may be constrained by the intrinsic concentration, a property of the material:

$${n}_{Intrinsic} \leq n = \frac{50}{9} \frac{ε}{m {μ}_{B u l k}^{2}} \qquad ( 76 )$$

### 4.3 the E×B Drift in a Superconductor

For economic reasons, the E×B drift should be supported by a magnetic field no stronger than that produced by a permanent magnet which is about IT. Since the product of mobility and the magnetic field μ_{Bulk}B_{z} must remain about equal to 4 as specified by equation (53), this upper bound on the field imposes a lower bound on mobility. A field of about 1 Tesla requires a mobility of 4 m²/V/s which is achievable with InAs around 250K.

Superconductors can easily satisfy the mobility requirement, but do not support the E×B drift because of the Meissner effect which expels the magnetic field from their bulk. The field, however, is not completely expelled: it penetrates the skin material down to the London depth. The electric field also has a penetration depth.

It is therefore possible to use a superconductor slab whose dimensions along the Z axis fall below the penetration depth of the magnetic field, and dimensions along the Y axis fall below the penetration depth of the electric field. In such a device, carriers exchange thermal energy in the return path and at the surfaces of the superconductor. The end result is a device with a forward channel comprised of a superconductor, which provides a mobility high enough to use a magnetic field generated by a permanent magnet.

### 4.4 Maximum Output Power

The above information can now be used to apply optimum values of n, μ_{Drude} and E_{y}² in equation (25):

$${P}_{LoadMax} = \frac{1}{16} \frac{{E}_{y}^{2}}{{ρ}_{Drude}} = \frac{1}{16} nq {μ}_{Drude} {E}_{y}^{2} \qquad ( 77 )$$

and calculate the maximum power output.

Since optimality requires that μ_{Drude}=1/2μ_{Bulk}=1/2μ_{Surfaces}, as per equation (43), equation (77) can be expressed as:

$${P}_{LoadMax} = \frac{1}{32} nq {μ}_{B u l k} {E}_{y}^{2} \qquad ( 78 )$$

Applying the optimal electrical field from equation (67) and the optimum carrier concentration from equation (75) yields the optimum power output:

$$P = \frac{125}{81} \frac{q ε {k}_{B} T}{{m}^{2} {μ}_{B u l k}^{3}} \qquad ( 79 )$$

The above equation gives the power per unit volume. The power per unit area, which may be useful in comparing the E×B effect with solar power, is obtained by multiplying equation (79) by the thickness of the device given by equation (59). Therefore, the maximum power per unit area for a device fully tuned to the thermodynamic threshold is:

$$Power per unit area = \frac{125}{27 \sqrt{5}} \frac{ε}{{μ}_{Bulk}^{2}} {( \frac{{k}_{B} T}{m} )}^{3 / 2} \qquad ( 80 )$$

The square of mobility in the denominator of equation (80) implies that more power can be achieved by operating with lower mobility materials and shorter mean free paths. However, permanent magnets and material properties have their limitations. InAs, one of the highest mobility materials, has a mobility of 3.73 m²/V/s at 250K. An InAs device operating at that temperature requires a magnetic field of B_{z}=4/μ_{Bulk}, =1.07 Tesla as shown by equation (53). This magnetic field is near the maximum that is achievable with a permanent magnet. Since magnetic field and mobility are inversely related for an optimum design, lowering mobility requires increasing the magnetic field beyond what is practically or economically feasible.

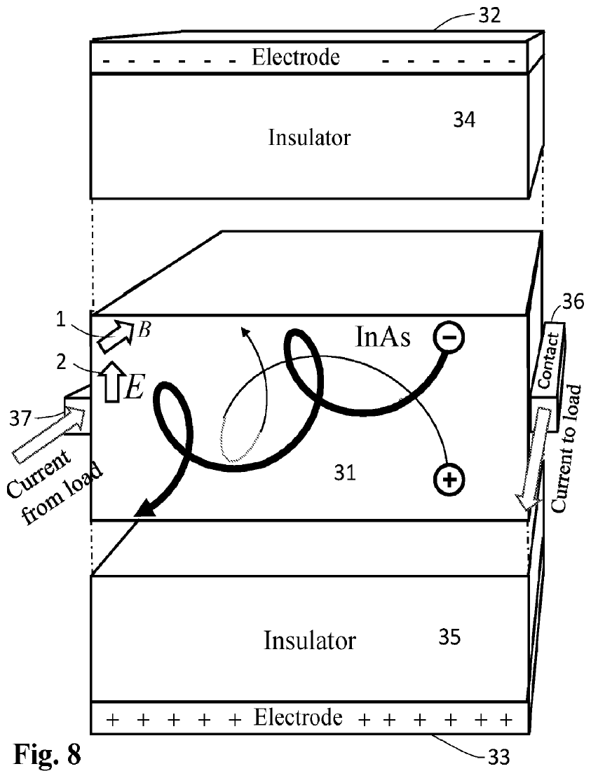

FIG. 8 illustrates the architecture of an E×B thermoelectric device. A semiconductor 31, for example made of InAs, in a sandwich between two insulated capacitor plates 32 and 33 where the insulation is shown as 34 and 35. Contact electrodes 36 and 37 can be positioned at an angle with respect to the X axis to favor one type of carrier over another (e.g., electrons over holes) or to tailor the voltage current ratio. The electric field 2 can also be produced by electrets, ferroelectrics, or junctions. The magnetic field 1 is produced by a permanent magnet not shown in the figure, with the direction shown as an arrow.

### 5. E×B Optimizing Calculator

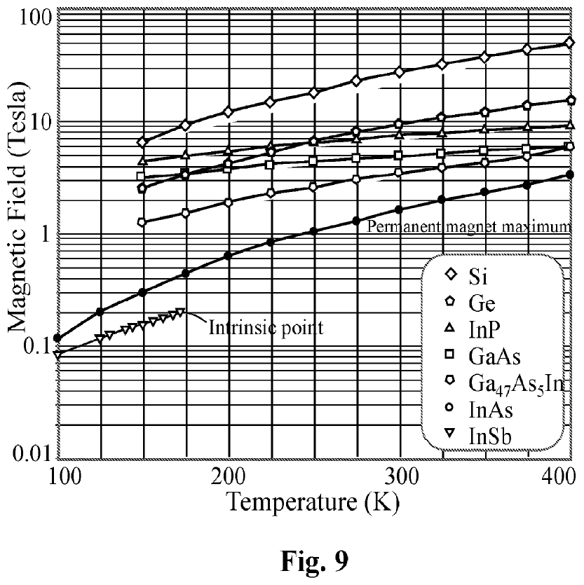

An optimizing calculator program has been developed that uses the design equations of the previous section. The optimization process is purely analytical. As explained, these equations optimize the power output of an E×B device by setting its operation to the thermodynamic threshold. A program in Visual Basic has been written that implements these equations which are summarized in Appendix A for the convenience of the reader. The input to this program consists of published data for material properties as a function of temperature such as mobility, effective mass, and permittivity. The program outputs optimum values for the B. and E, field, doping level, geometrical configuration, and electrical load. It was used to calculate expected performance data for several semiconductors as shown in Tables I to VII below and presented in FIGS. 9-11.

Several materials have been evaluated for this application including InAs, InSb, Ga₄₇As₅In, GaAs, InP, Ge and Si. Ideally a material should have an operational temperature slightly below ambient to facilitate thermal inflow from the environment. For example, if ambient temperature is 300K, an E×B device could run at around 250K to allow for the inflow of heat. As thermal energy converted to electrical energy is transferred to the load, the temperature of the device falls below ambient. Temperature equilibrium is reached when the outflow of electrical energy to the load is equal to the inflow of thermal energy from the heat bath. The resulting equilibrium temperature should be the same as the optimal operation temperature selected by the designer.

In addition, the material should require a magnetic field low enough to be produced by a permanent magnet, for example around 1T. By these measures, Indium Arsenide has been found to be a suitable material near or below room temperature, for example around 250K to 300K. InSb operates best around 150K to 170K. Composites such as InAsₓSb₁₋ₓ offer the advantage of having a tunable operational temperature. Doped graphene also provides low mobility suitable for the E×B drift.

Note that the suggested temperature difference (for example in the InAs implementation of 50K between the ambient 300K and operational temperatures 250K) is not a Carnot cycle requirement. This difference arises because the device cools itself as it operates and is in fact necessary for the inflow of heat into the device.

FIG. 9 presents a set of curves for the optimum magnetic field plotted as a function of temperature for several semiconductors. Indium Arsenide requires a magnetic field of 1.67T at 300K but only 1.07T at 250K, a better operating temperature to facilitate thermal inflow. In comparison, Indium Antimonide operates best around 150K to 170K where the power output is low. Silicon, Germanium, Indium Phosphide, and Gallium Arsenide are unpractical as they require a minimum field ranging from 5 to 30 Teslas at room temperature. Combining elements is a noteworthy method to optimize the properties of the semiconductor to a desired operating temperature. As the graph shows, combining Ga with InAs to form Ga₄₇As₅In raises the operating temperature of the material, while combining Sb with In to form InSb lowers it. The combination InAsₓSb₁₋ₓ can also be used to adjust the operating temperature of the device.

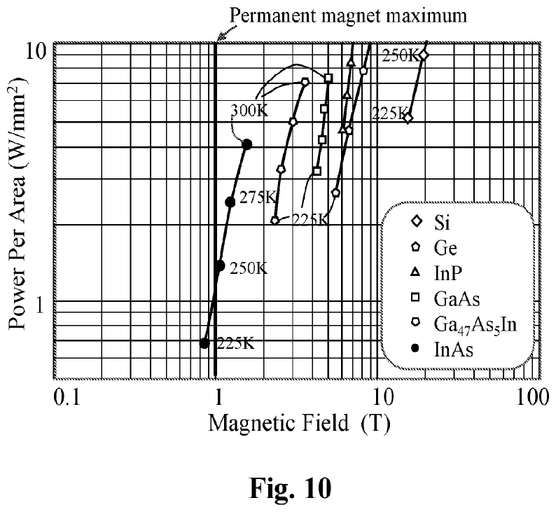

FIG. 10 is a graph of the power output per unit area as a function of the magnetic field for InAs, Ga₄₇As₅In, GaAs, InP, Ge and Si. The figure shows that InAs is the preferred semiconductor as it operates best with a magnetic field near one Tesla around 250K.

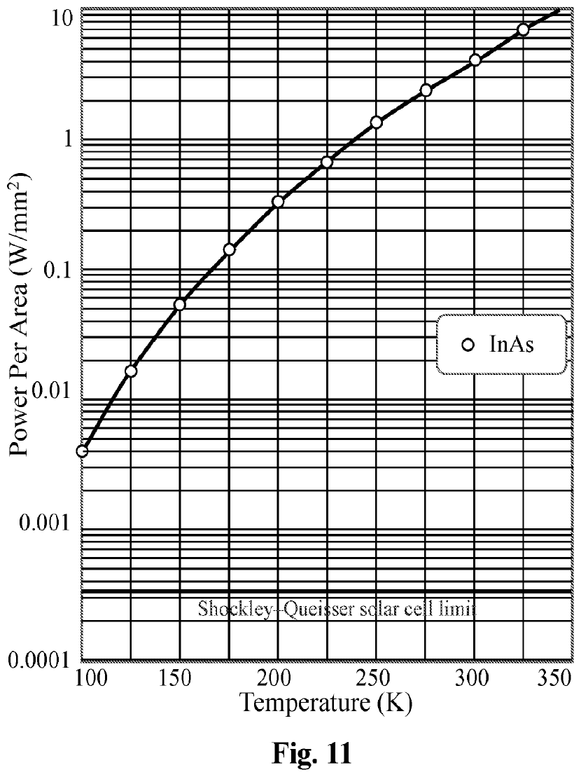

FIG. 11. This figure shows the power output per unit area for an InAs device. At 250K with a magnetic field of 1.07T, the maximum power output under ideal conditions is 1337 mW/mm².

Table I shows design information calculated using material property data obtained from [16] for an E×B device using InAs, fully tuned to operate at the thermodynamic threshold. A slab of InAs tuned to the thermodynamic threshold, using ambient heat at 300K, operating at 250K, with a magnetic field of 1.07T, with a thickness and length of 265 nm can produce up to 1337 mW/mm² or 3967 times more power than the Shockley-Queisser solar cell limit of 0.337 mW/mm². [17,18].

### Table I Legend

T=Operating temperature.
μ_{Bulk}=Carrier mobility.
n_{Int}=Intrinsic carrier concentration.
n_{Opt}=Optimum carrier concentration.
B_{z}=Magnetic field.
E_{y}=Electric field.
ρ_{y}=device thickness.
δₓ=device length.
V_{Load}=Voltage across the device or the load.
P=Power output per unit area.

TABLE I
Indium Arsenide

| T (K) | 100 | 125 | 150 | 175 | 200 | 225 | 250 | 275 | 300 | 325 | 350 |
|---|---|---|---|---|---|---|---|---|---|---|---|
| μ_{Bulk}(m²/V/s) | 34.0 | 19.8 | 12.8 | 8.81 | 6.38 | 4.81 | 3.73 | 2.96 | 2.40 | 1.98 | 1.65 |
| n_{Int} × 10¹⁸(m⁻³) | ~0.0 | ~0.0 | 0.08 | 1.06 | 7.56 | 35.7 | 126 | 359 | 869 | 1856 | 3589 |
| n_{Opt} 10¹⁸ (m⁻³) | 30.7 | 90.3 | 218 | 458 | 873 | 1541 | 2562 | 4058 | 6175 | 9087 | 12993 |
| B_{z} (T) | 0.12 | 0.20 | 0.31 | 0.45 | 0.63 | 0.83 | 1.07 | 1.35 | 1.67 | 2.02 | 2.42 |
| E_{y} (V/mm) | 22.5 | 43.1 | 73.3 | 115 | 170 | 239 | 325 | 429 | 552 | 697 | 865 |
| δ_{y} (nm) | 1531 | 999 | 705 | 525 | 406 | 325 | 265 | 221 | 187 | 161 | 139 |
| δₓ (nm) | 1531 | 999 | 705 | 525 | 406 | 325 | 265 | 221 | 187 | 161 | 139 |
| V_{Load} (mV) | 8.62 | 10.8 | 12.9 | 15.1 | 17.2 | 19.3 | 21.5 | 23.7 | 25.9 | 28.0 | 30.2 |
| P (mW/mm²) | 4.06 | 16.7 | 52.8 | 140 | 326 | 687 | 1337 | 2444 | 4238 | 7032 | 11238 |

TABLE II
Indium Antimonide

| T (K) | 75 | 100 | 125 | 130 | 140 | 150 | 155 | 160 | 165 | 170 |
|---|---|---|---|---|---|---|---|---|---|---|
| μ_{Bulk} (m²/V/s) | 76.9 | 47.7 | 32.9 | 30.9 | 27.3 | 24.3 | 23.0 | 21.9 | 20.8 | 19.8 |
| n_{Int} × 10¹⁸(m⁻³) | ~0.0 | 0.17 | 4.31 | 7.17 | 18.0 | 40.3 | 58.4 | 82.7 | 115 | 157 |
| n_{Opt} 10¹⁸ (m⁻³) | 10.96 | 28.5 | 59.7 | 68.0 | 87.0 | 109 | 122 | 136 | 150 | 166 |
| B_{z} (T) | 0.05 | 0.08 | 0.12 | 0.13 | 0.15 | 0.164 | 0.174 | 0.183 | 0.193 | 0.202 |
| E_{y} (V/mm) | 11.0 | 20.6 | 33.3 | 36.2 | 42.5 | 49.4 | 53.0 | 56.8 | 60.7 | 64.7 |
| δ_{y} (nm) | 2340 | 1676 | 1294 | 1236 | 1134 | 1047 | 1008 | 972 | 938 | 906 |
| δₓ (nm) | 2340 | 1676 | 1294 | 1236 | 1134 | 1047 | 1008 | 972 | 938 | 906 |
| V_{Load} (mV) | 6.46 | 8.62 | 10.8 | 11.2 | 12.06 | 12.9 | 13.4 | 13.8 | 14.2 | 14.6 |
| P (mW/mm²) | 1.21 | 4.82 | 14.1 | 17.1 | 24.4 | 34.0 | 39.9 | 46.5 | 53.9 | 62.2 |

TABLE III
Gallium 47 Indium 5 Arsenide

| T (K) | 125 | 150 | 175 | 200 | 225 | 250 | 275 | 300 | 325 | 350 |
|---|---|---|---|---|---|---|---|---|---|---|
| μ_{Bulk}(m²/V/s) | 4.1 | 3.2 | 2.5 | 2.08 | 1.75 | 1.50 | 1.31 | 1.15 | 1.02 | 0.92 |
| n_{Int} 10¹⁸(m⁻³) | ~0. | ~0. | ~0. | ~0. | ~0. | 0.02 | 0.111 | 0.56 | 2.19 | 7.17 |
| n_{Opt} 10¹⁸(m⁻³) | 1078 | 1837 | 2878 | 4247 | 5986 | 8137 | 10742 | 13842 | 17479 | 21692 |
| B_{z} (T) | 0.97 | 1.27 | 1.59 | 1.93 | 2.29 | 2.67 | 3.06 | 3.48 | 3.91 | 4.35 |
| E_{y} (V/mm) | 156 | 222 | 301 | 390 | 492 | 604 | 728 | 863 | 1010 | 1167 |
| δ_{y} (nm) | 277 | 233 | 201 | 177 | 158 | 143 | 130 | 120 | 111 | 103 |
| δₓ (nm) | 277 | 233 | 201 | 177 | 158 | 143 | 130 | 120 | 111 | 103 |
| V_{Load} (mV) | 10.8 | 12.9 | 15.0 | 17.2 | 19.3 | 21.5 | 23.7 | 25.9 | 28 | 30.2 |
| P(mW/mm²) | 149 | 334 | 659 | 1188 | 1999 | 3182 | 4846 | 7116 | 10131 | 14052 |

TABLE IV
Gallium Arsenide

| T (K) | 150 | 175 | 200 | 225 | 250 | 275 | 300 | 325 | 350 |
|---|---|---|---|---|---|---|---|---|---|
| μ_{Bulk}(m²/V/s) | 1.27 | 1.15 | 1.05 | 0.97 | 0.90 | 0.85 | 0.80 | 0.76 | 0.72 |
| n_{Int} 10¹⁸(m⁻³) | ~0 | ~0 | ~0 | ~0 | ~0. | ~0. | ~0. | ~0. | ~0. |
| n_{Opt} 10¹⁸(m⁻³) | 6856 | 8420 | 10061 | 11772 | 13547 | 15384 | 17276 | 19222 | 21218 |
| B_{z} (T) | 3.15 | 3.49 | 3.82 | 4.13 | 4.43 | 4.72 | 5.00 | 5.27 | 5.54 |
| E_{y} (V/mm) | 446 | 534 | 624 | 716 | 809 | 905 | 1001 | 1099 | 1198 |
| δ_{y} (nm) | 116 | 113 | 111 | 108 | 106 | 105 | 103 | 102 | 101 |
| δₓ (nm) | 116 | 113 | 111 | 108 | 106 | 105 | 103 | 102 | 101 |
| V_{Load} (mV) | 12.9 | 15.1 | 17.2 | 19.3 | 21.5 | 23.7 | 25.9 | 28.0 | 30.1 |
| P (mW/mm²) | 1005 | 1556 | 2271 | 3171 | 4274 | 5599 | 7164 | 8988 | 11088 |

TABLE V
Indium Phosphide

| T (K) | 150 | 175 | 200 | 225 | 250 | 275 | 300 | 325 | 350 |
|---|---|---|---|---|---|---|---|---|---|
| μ_{Bulk}(m²/V/s) | 0.89 | 0.80 | 0.73 | 0.67 | 0.62 | 0.58 | 0.54 | 0.51 | 0.48 |
| n_{Int} 10¹⁸(m⁻³) | ~0 | ~0 | ~0 | ~0 | ~0. | ~0. | ~0. | ~0. | 0.001 |
| n_{Opt} 10¹⁸(m⁻³) | 10564 | 13217 | 16048 | 19045 | 22198 | 25496 | 28934 | 32504 | 36201 |
| B_{z} (T) | 4.48 | 5.01 | 5.52 | 6.01 | 6.49 | 6.95 | 7.41 | 7.85 | 8.29 |
| E_{y} (V/mm) | 562 | 679 | 800 | 925 | 1052 | 1183 | 1316 | 1452 | 1590 |
| δ_{y} (nm) | 92 | 89 | 86 | 84 | 82 | 80 | 79 | 77 | 76 |
| δₓ (nm) | 92 | 89 | 86 | 84 | 82 | 80 | 79 | 77 | 76 |
| V_{Load} (mV) | 12.9 | 15.1 | 17.2 | 19.4 | 21.5 | 23.7 | 25.9 | 28.0 | 30.2 |
| P(mW/mm²) | 1374 | 2167 | 3215 | 4552 | 6214 | 8235 | 10648 | 13488 | 16788 |

TABLE VI
Germanium

| T (K) | 150 | 175 | 200 | 225 | 250 | 275 | 300 | 325 | 350 |
|---|---|---|---|---|---|---|---|---|---|
| μ_{Bulk}(m²/V/s) | 1.6 | 1.19 | 0.92 | 0.73 | 0.60 | 0.50 | 0.42 | 0.36 | 0.31 |
| n_{Int} 10¹⁸(m⁻³) | ~0 | 0.0002 | 0.006 | 0.089 | 0.760 | 4.48 | 20.0 | 71.8 | 217 |
| n_{Opt} 10¹⁸(m⁻³) | 2846 | 5160 | 8640 | 13613 | 20445 | 29536 | 41325 | 56285 | 74924 |
| B_{z} (T) | 2.5 | 3.37 | 4.36 | 5.47 | 6.70 | 8.05 | 9.52 | 11.1 | 12.8 |
| E_{y} (V/mm) | 256 | 373 | 516 | 687 | 887 | 1118 | 1382 | 1678 | 2010 |
| δ_{y} (nm) | 202 | 162 | 134 | 113 | 97 | 85 | 75 | 67 | 60 |
| δₓ (nm) | 202 | 162 | 134 | 113 | 97 | 85 | 75 | 67 | 60 |
| V_{Load} (mV) | 12.9 | 15.1 | 17.2 | 19.4 | 21.5 | 23.7 | 25.9 | 28.0 | 30.2 |
| P (mW/mm²) | 302 | 691 | 1413 | 2657 | 4673 | 7789 | 12417 | 19070 | 28369 |

TABLE VII
Silicon

| T (K) | 150 | 175 | 200 | 225 | 250 | 275 | 300 | 325 | 350 |
|---|---|---|---|---|---|---|---|---|---|
| μ_{Bulk} m²/V/s) | 0.60 | 0.43 | 0.33 | 0.26 | 0.21 | 0.17 | 0.14 | 0.12 | 0.10 |
| n_{Int} 10¹⁸(m⁻³) | ~0 | ~0 | ~0 | ~0. | ~0. | 0.001 | 0.009 | 0.059 | 0.305 |
| n_{Opt} 10¹⁸(m⁻³) | 6784 | 12945 | 22657 | 37121 | 57733 | 86086 | 123975 | 173400 | 236572 |
| B_{z} (T) | 6.68 | 9.23 | 12.2 | 15.6 | 19.5 | 23.8 | 28.6 | 33.8 | 39.5 |
| E_{y} (V/mm) | 466 | 695 | 983 | 1335 | 1754 | 2246 | 2816 | 3467 | 4202 |
| δ_{y} (nm) | 111 | 87 | 70 | 58 | 49 | 42 | 37 | 32 | 29 |
| δₓ (nm) | 111 | 87 | 70 | 58 | 49 | 42 | 37 | 32 | 29 |
| V_{Load} (mV) | 12.9 | 15.1 | 17.2 | 19.4 | 21.5 | 23.7 | 25.9 | 28.1 | 30.2 |
| P(mW/mm²) | 490 | 1177 | 2517 | 4922 | 8965 | 15423 | 25307 | 39912 | 60854 |

### 6. Simulation of E×B Device

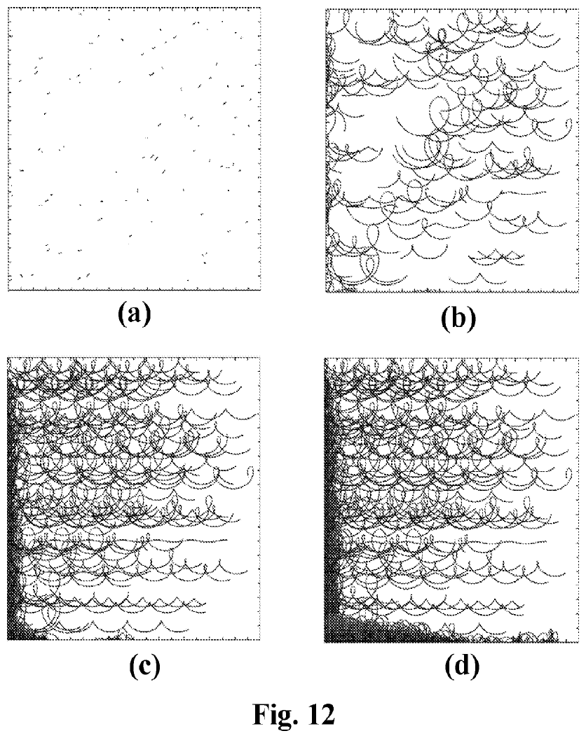

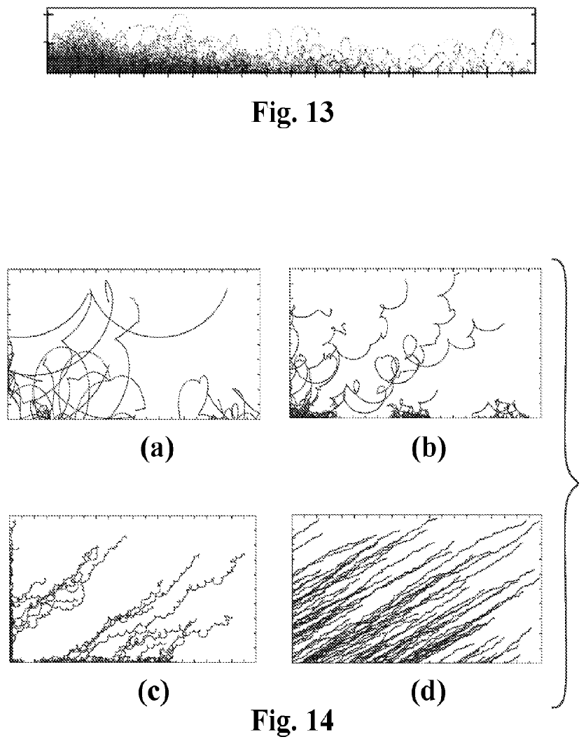

A simulator has been developed in Visual Basic to simulate the forward channel of an E×B device. The program allows the user to specify the number of carriers being simulated, their temperature, mobility, and effective mass, as well as the electric and magnetic fields and the dimension of the channel. The program uses this information to calculate and display the particles' average orbital radius and the isothermal scale height. The particles are initially positioned at random locations throughout the chamber. As predicted by the theory, they follow cycloid paths in accordance with the fields. As shown in FIGS. 12, 13, and 14, the program allows the user to observe the particles as they interact with each other and undergo collisions in the medium of the simulation chamber. This simulation confirms the theory that:
1) Charged particles carried by the E×B drift move unidirectionally until they encounter an obstacle such as the wall of the simulation chamber as shown in FIG. 12.
2) The accumulation of particles creates a space charge as illustrated in FIG. 13.
3) The drift angle is a function of mobility. When mobility is infinite, the drift angle is 0° from the horizontal. When mobility is too low for cycloids to form, particles drift down almost vertically. When the product of mobility and magnetic field μB_{z}==2, the drift angle is 26.57°. FIG. 14 shows the drift at different scales. Particles move diagonally down and to the left with a drifting angle of 26.57 degrees from the horizontal for T=300K, E_{y}=328V/mm upward, B_{z}==1 Tesla “into the paper,” and μ=2.

In FIG. 12 frames (a) through (d) are time-lapse images of an E×B simulation of negatively charged particles in a chamber. Width=2 microns; Length=2 microns; E=328000V/m pointing upward; B_{z}=1T “into the paper”; T=300K; mobility=∞; and effective mass=0.023. Red trajectories represent particles moving right, and blue ones moving left, up, or down. (a) The particles begin at randomly distributed positions (b) are carried by the E×B drift toward the left wall, (c) accumulate on the left wall, (d) dribble down the left wall and accumulate on the floor in the bottom left corner.

FIG. 13 shows the final particle distribution on the floor of the simulation illustrated in FIG. 10. The particles accumulate on one side of the simulation chamber.

FIG. 14 shows the drift of negatively charged particles at different scales. The particles start out randomly distributed in a box and drift diagonally down and to the left with a drifting angle of 26.57 degrees from the horizontal, as predicted by the theory. T=300K, E=328V/m upward and B==1 Tesla “into the paper,” and μ=2. (a) Number of particles=10. The box is 0.5 microns×0.25 micron. (b) Number of particles=20. The box is 2 microns×1 micron. (c) Number of particles=20. The box is 10 microns×5 microns. (d) Number of particles=100. The box is 100 microns×50 microns.

### 7. Construction of Device

This section covers the following design topics:
Source and arrangement of the electric field.
Control of semiconductor surface conductivity by surface doping and reticulation.
Positioning the contacts.
Series and parallel connection.
Alternating layer polarization.
Source of the magnetic field.
Matched load.
Ohmic contacts.
Self-sustaining operating temperature.
Self-sustaining electric field.
Temperature priming.
Shorting thermal flow to enhance electrical output.
No need for a heat sink.
Increase in energy production with temperature.
Substrate.
Doping.
Applications.

### 7.1 Source and Arrangement of the Electric Field

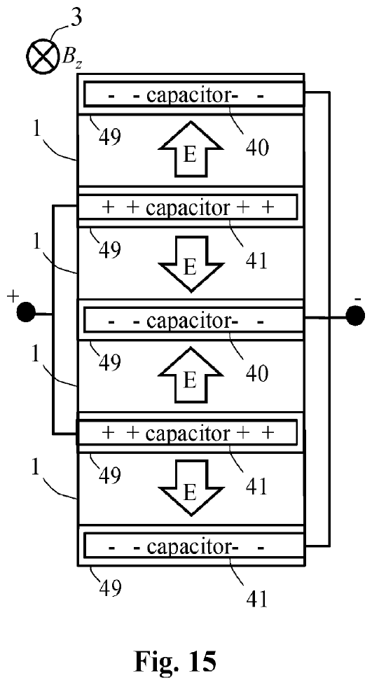

Several configurations can be used to produce this field. As shown in FIG. 15, insulated capacitor plates 40 and 41 covered with an insulating layer 49 can be inserted between the semiconductor layers 1 arranged in a stack. Assigning opposite polarity to alternating insulated capacitor plates allows the plates inside the stack to serve double duty, that is, provide a field E, above and below itself in the stack. One advantage of the capacitor plate design is that the electric field can be adjusted and even reversed, thereby controlling the operation of the E×B drift, which may be useful for priming the device.

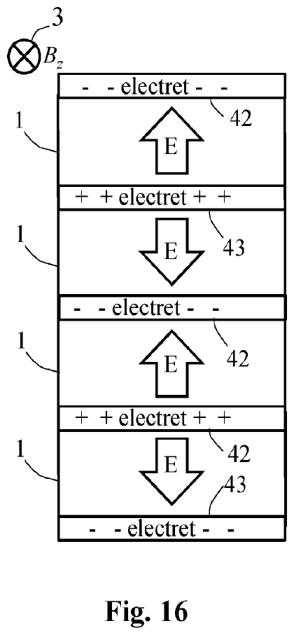

The electric field can also be produced by electrets 42 and 43 as shown in FIG. 16. The advantage of the electret design is that the charges are permanent and do not have to be actively maintained. The electret charges can be configured to alternate from one layer to the next, thereby allowing each electret to serve double duty by providing a field above and below itself in the stack. Ferroelectric materials can also be used in place of electrets.

Yet another approach for generating an electric field across the stack layers is to insert between the stack layers alternating materials with different work functions.

Yet another way of generating an electric field is by joining two different materials thereby forming a heterojunction.

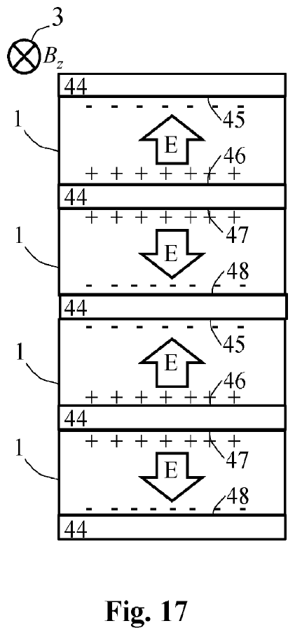

Yet another method of producing an electric field across the stack layers is to use the built-in potential of a junction by applying a surface doping to each layer, thereby creating a junction at the surface, with the bulk of the layer operating mostly in depletion mode to prevent space charges from accumulating and canceling the electric field. FIG. 17 shows a configuration in which the layers are separated by an insulator 44. The surface doping is applied to the top and bottom surface of each layer, each layer of the stack alternatingly being n-doped/p-doped and p-doped/n-doped. In other words, a first layer is n-doped on the top surface 45 and p-doped on the bottom surface 46, and the layer below is p-doped on the top surface 47 and n-doped on the bottom surface 48. This arrangement ensures that the E field reinforces itself from one layer to the next. The bulk of the layer material could be intrinsic or lightly doped. The surface is significantly more heavily doped to ensure that an electric field is created by the built-in potential at the surface junction.

Clearly, a combination of the above electric field sources is possible, for example combining electrets with insulated capacitor plates, to achieve charge permanence for operation yet flexibility, for example, for priming the device at the beginning of its operation.

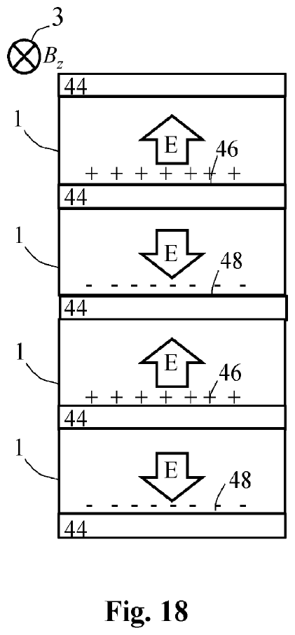

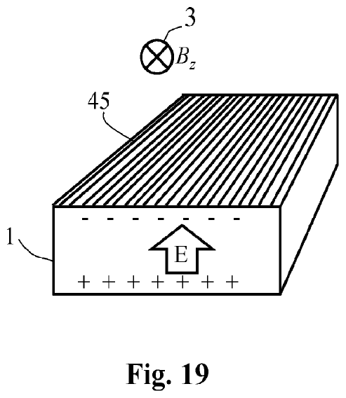

In FIG. 18 the surface doping is applied to only one side of each layer. In this configuration, the polarity of the doping alternates from n-doped 48, to p-doped 46 such that the electric field produced by each doping is shared between two adjacent layers.

### 7.2 Control of Semiconductor Surface Conductivity by Surface Doping and Reticulation

Doping the surface of a semiconductor layer can increase the ohmic conductivity of the layer and inhibit the E×B drift at the layer, thereby short circuit the desired power output. To avoid this problem, the surface can be made conductively anisotropic by reticulating or striating the doping in a direction perpendicular to the desired low conductivity axis (i.e., the X axis). In other words, the striation would be along the Z axis. FIG. 19 illustrates a reticulated or striated doping 45 in which the striations are in the Z direction designed to reduce the surface conductivity in the X direction. This technique prevents backward current leakage through the doped surface, in a direction opposite to the E×B drift current.

### 7.3 Positioning the Contacts

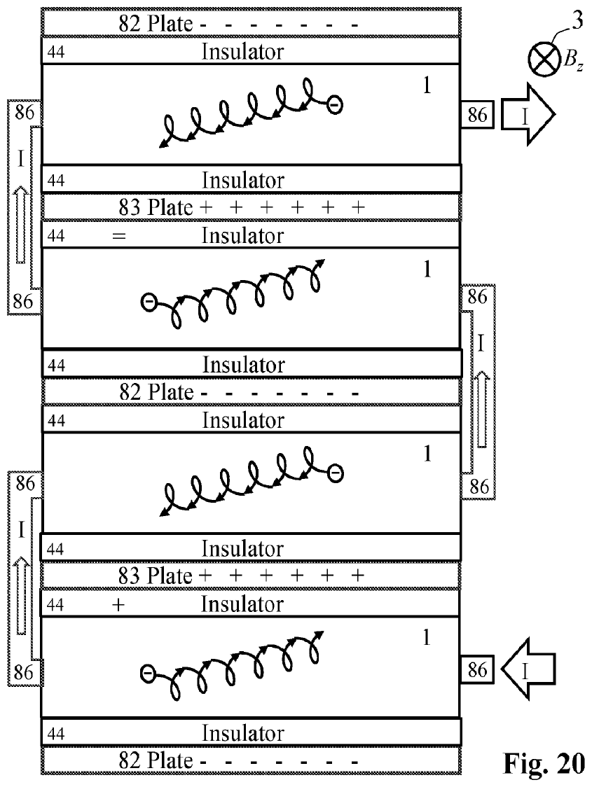

As carriers follow their cycloidal paths, they go up and down the electrical potential gradient and therefore, continuously exchange potential energy and kinetic energy. They reach their minimum potential energy and maximum kinetic energy at the bottom of the cycloid, and vice versa, their maximum potential energy and minimum kinetic energy at the top. Consequently, the position of contact points upstream and downstream across the semiconductor affects the voltage and current produced by the carriers. This idea is exemplified in FIG. 20-22. FIG. 20 shows a device arranged in a stack with the contact points 86 centrally located between two capacitor plates 82 and 83, the two points positioned along an axis parallel to the X axis. The capacitor plates 82 and 83 are insulated by layers 44. In addition, the plates alternate in polarity to serve as double duty in each layer of the stack.

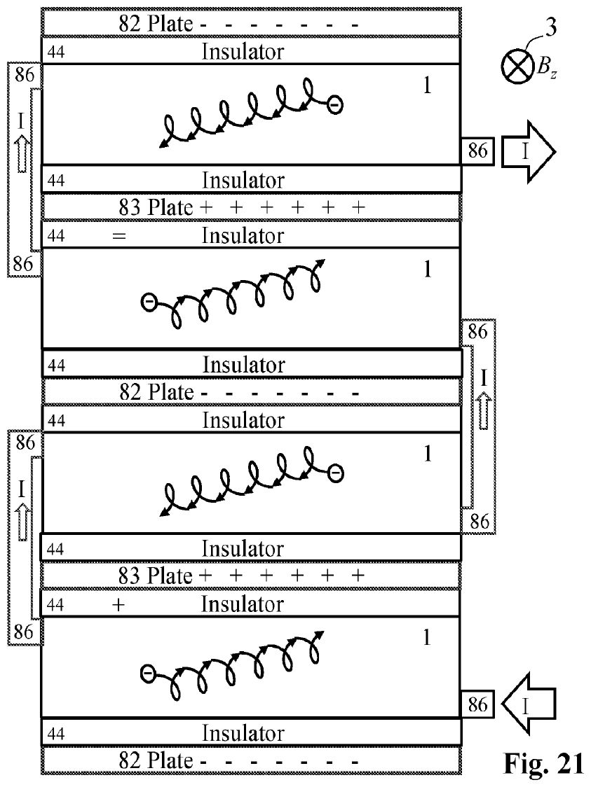

In FIG. 21, the contact points 86 are located along an axis antidiagonal to the drift. This configuration ensures that the carriers' potential energy is minimum at the beginning and maximum at the end of the carriers' paths and therefore results in a maximum voltage.

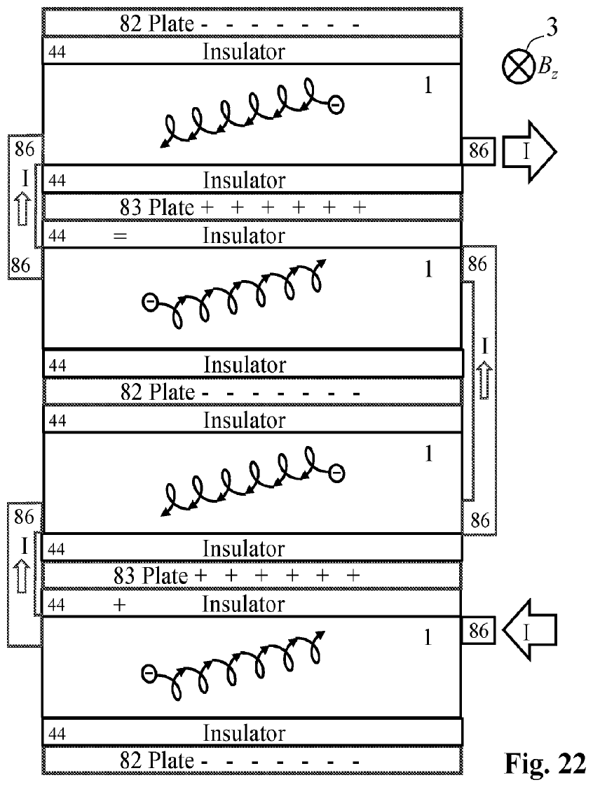

In FIG. 22, shows a configuration in which both contact points 86 are at the floor of the semiconductor 1.

In general, contact can be positioned to suit the need of the designer, along an axis parallel to the X axis, either at the floor, at the ceiling or centrally located across the semiconductor 1. They can also be located at an angle with respect to the X axis to maximize the voltage output.

### 7.4 Series and Parallel Connection.

Multiple forward channels can be connected in series or in parallel, to additively contribute voltage or current, respectively.

### 7.5 Alternating Layer Polarization

The semiconductor layers can be arranged in a stack, each layer in the stack electrically insulated from each other (except for connections) and incorporating or sharing their source of electric field. As shown in FIGS. 15-18, 20-22, the field within each layer mutually reinforce by stacking the layers such that their polarities alternate (upward/downward/upward/downward . . . ). This approach maximizes the electric field across each semiconductor layer and minimizes the electric field across the insulation layers.

### 7.6 Source of the Magnetic Field

The magnetic field is configured to be parallel to the stack layers. The field can be produced by permanent magnets, electromagnets, or superconducting magnets. For economic reasons, one may choose to restrict the magnetic source to permanent magnets which have the clear advantage of low operating cost, low maintenance, and requiring no cooling and no continuous power input. Materials composing permanent magnets, include but are not limited to, neodymium iron boron alloys, iron nitride, samarium cobalt iron, copper zirconium alloys, strontium ferrite, aluminum, and iron and cobalt alloys (alnico). Neodymium magnets and iron nitride magnets are among the strongest. The source of the magnetic field can be positioned outside the semiconductor layer or embedded inside the material or on its surface. The source of the magnetic field can also be built in the bulk of the semiconductor or on its surface.

Permanent magnets have no operational cost, but their strength is limited to below about 1.5 Tesla. To maximize the power output, the product of the bulk mobility and the magnetic field μ_{Bulk}B_{z} should be between 1 and 10, preferably between 1.9 and 6, even more preferably between 1.9 and 4.1, and yet preferably between 3.9 and 4.1. Therefore, a limit on the strength of the magnetic field restricts the mobility of the carriers, and the choice of materials and operating temperatures. It is important therefore to consider the following magnetic field focusing techniques.

Even though a single permanent magnet has a limited field strength, this field can be increased by combining magnets together, for example by means of two magnets in a N-S, N-S configuration with the semiconductor material in a sandwich between them, by using C-shaped or H-shaped magnets, by means of ferromagnetic material to create a magnetic circuit that focuses the magnetic field onto the semiconductor, or by using a combination of magnets configured as a Halbach array. The technology for focusing strong magnetic fields from permanent magnets is well known and can be found in the technical literature.

### 7.7 Matched Load

As illustrated in FIGS. 4 and 5, a load alters the operational characteristics of the device because the voltage across the load generates a back EMF along the X axis of the device, which deflects the primary electric field, E_{y}. Therefore, a matched load must be matched, not to the unloaded device, but to the E×B device in its loaded operating state as shown in FIG. 5.

### 7.8 Ohmic Contacts

Contacts with the semiconductor can also be designed to favor either holes or electrons. One can design contact to favor the overriding carriers to maximize the current output. There are two ways of making ohmic contacts:
1. For electron injection, choose metals of low work functions (below the work function of the semiconductor) for metal-n-type semiconductor junction or metal-intrinsic semiconductor junction. For hole injection choose metals with high work function (greater than the work function of the semiconductor) for metal-p-type semiconductor junctions. This lowers the potential barrier for efficient thermionic emission to make the free carrier density higher at the contact than that in the bulk of the semiconductor. The first approach is usually difficult because it is hard to find a suitable metal with the appropriate low work function to contact to n-type semiconductors, or large enough to contact to p-type semiconductors.
2. Dope the semiconductor surface heavily near the contact to make the potential barrier thin enough for efficient quantum-mechanical tunneling. A very thin layer is heavily doped with dopants by either diffusion or ion implantation techniques in order to make this layer become degenerate. Such a layer is called the n⁺ layer for n-type semiconductors and the p⁺ layer for p-type semiconductors. After this layer has been produced, any metal or alloy can be deposited on the surface of this layer to form a good ohmic contact. For example, the metal indium forms a good ohmic contact with InSb, InAs or HgCdTe. Taking the ohmic contact for n-type semiconductors as an example, the n⁺ layer provides a narrow barrier width for electrons to tunnel quantum-mechanically from the metal electrode to the conduction band of the semiconductor.

### 7.9 Self-Sustaining Operating Temperature

Under normal operation, energy flows in and out of the device in the form of thermal and electrical energy. When its net power input is equal to its net power output, the device reaches temperature equilibrium which, obviously, is a self-sustaining state. Since heat must flow from the heat source into the device, the device must operate at a lower temperature than the heat source. The temperature of this self-sustaining state can be controlled by adjusting the thermal connection between the device and the heat source. A high thermal conductivity raises the temperature of the device toward the heat source, and vice versa a low thermal conductivity allows the temperature of the device to drop. The temperature of the self-sustaining state could also be controlled by adjusting how much power is drawn by the electrical load. Increasing the power drawn from the device lowers its temperature, and vice versa, drawing less power increases it. For example, the heat source could be at ambient temperature, (for example 300K) and the optimum operating temperature of the device could be below ambient, (for example at 273K). At the beginning of its operation, the device could be at ambient temperature, and would have to cool itself by outputting power to reach its optimum operational temperature.

### 7.10 Self-Sustaining Electric Field

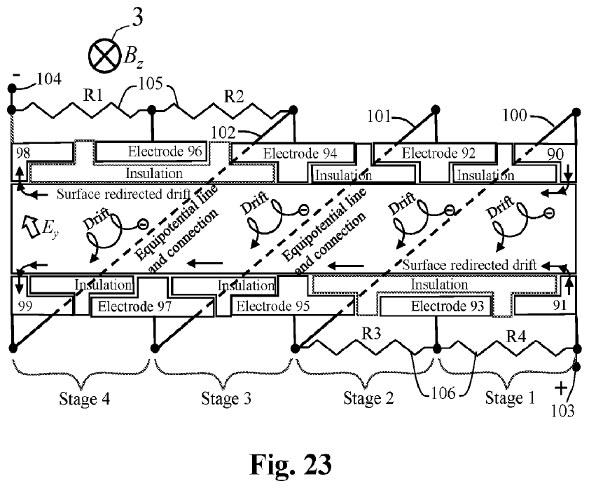

As shown in FIG. 23, a device can generate the voltage required to charge its own capacitor plates in a self-sustaining manner. As carriers begin their drift upstream along the floor of a multistage device, the downstream charge displacement generates a potential difference between capacitor plates 91 and 95 at the floor of adjacent stages (two are shown in the figure). This potential generated at the floor is sufficiently high to apply a charge between the floor capacitor plate 91 and the ceiling capacitor plates 90 across the semiconductor for the first upstream stage. This is done by means of a connection 100 between the capacitor plate 90 at the ceiling of the first upstream stage to one of the downstream floor capacitor plates 95 (the second one in the figure). This arrangement can be configured in a cascading manner connecting 92 to 97 and 94 to 99 to ensure that all capacitors are charged. Note that these connections 100, 101, and 102 coincide with the equipotential lines which are perpendicular to the electric field. The high impedance resistors 105 and 106 operate as voltage dividers to define the voltages applied to the intermediate capacitor plates 93 and 96. To begin operation, the electric field in the device may have to be primed. This is done by applying a voltage between the input 103 and output 104 ports. The resulting electric fields between the capacitor plates then become self-sustaining for the whole device.

### 7.11 Temperature Priming

A device optimized for a particular temperature may not begin its operation at that temperature, and therefore may not be capable, given its design parameters to reach its optimum operating state. It may be necessary to prime the device, that is, to temporarily modify its design parameters at the beginning of operation to enable it to reach its optimum design temperature, thereby allowing it to achieve self-sustainability. Certain parameters such as the thickness of the semiconductor layer or doping which are set at fabrication time, cannot be easily altered at operation time. However, other parameters can be changed. These include:
1. The electric field,
2. The magnetic field,
3. The electrical load,
4. The thermal conductance linking the device to the heat source.

The electric field can be modified if it is produced by capacitor plates. The magnetic field can also be changed even if it is produced by a permanent magnet, by modifying the geometry of the device or by adding or subtracting from the primary (permanent magnet) field using an electro-magnet for example.

Priming can also be achieved by changing the thermal conductivity of the contact to the heat source. An E×B drift device optimally designed, for example, for 200K and that begins its operation, for example at a heat source temperature of 300K, works sub-optimally at the higher temperature and may not be capable of cooling itself sufficiently to reach its optimum working temperature. However, it may still produce some power. The device can be made to reach its design temperature by temporarily decreasing the thermal conductivity to the heat source, thereby reducing the input heat flow. A simple method of altering the thermal conductance between a heat source and the semiconductor is simply to connect or disconnect the thermal contact. In the case discussed above, the device would begin its operation at 300K with the thermal contact disconnected. The contact would then be reestablished when the temperature of the device reaches 200K.

Similarly, a device optimized for a high temperature but starting at a low temperature, can be primed by increasing the thermal connection with the heat source.

Priming can also be achieved by thermally connecting several E×B drift devices each optimized for a different temperature. For example, a first device could be optimized for the initial operating temperature and second, for the final steady-state operating temperature.

Yet another priming approach is to use a Peltier device to bring the E×B drift device to its operational temperature.

### 7.12 Shorting Thermal Flow to Enhance Electrical Output

In the presence of a significant work function at the junctions between the forward and return channels, a Peltier effect could develop which would raise the temperature of one junction and lower the temperature of the other. This thermal effect can be maximized by shorting the current in the return path. Conversely, if the purpose of the device is to generate electrical energy, then the junctions should be thermally shorted.

### 7.13 No Need for a Heat Sink

The reliance of the E×B drift on a field configuration and not on a temperature gradient significantly improves performance. Consider an E×B device operating with the highest possible efficiency permitted by conventional thermodynamics (i.e., the Carnot limit). Furthermore, let the heat source be at T_{H}=ambient temperature (e.g., 300K) and the heat sink at T_{C}=0° K. While a temperature of 0° is physically impossible to achieve and forbidden by the second law, the analysis below demonstrates that the heat sink at 0° K requirement is actually not necessary and can be jettisoned. Temporarily assuming that T_{C}=0° K. is possible, the efficiency of the device with a magnetic field and operating between T_{H} and T_{C}=0° K is:

$${η}_{Actual} = {η}_{Carnot} = \frac{{T}_{H} - 0}{{T}_{H}} = 1 \qquad ( 81 )$$

which implies that:

$${η}_{Actual} = \frac{W}{{Q}_{H}} = 1 \qquad ( 82 )$$

further implying that the heat dumped to the heat sink is zero.

$${Q}_{C} = 0 \qquad ( 83 )$$

Since the waste heat is zero, there is no need for a heat sink in the first place, and the questionable temperature T_{C}=0° K becomes irrelevant. Therefore, the physical laws are upheld, the device operates at the Carnot efficiency limit, which is maximized to 1, i.e., η_{Actual}=η_{Carnot}=1, and the work produced by the device is equal to the input heat. i.e., W=Q_{H}. A heat source is required to replenish heat converted to electrical energy, but no heat sink is necessary.

7.14 Increase in Energy Production with Temperature

Since a heat sink is not necessary the device can operate using ambient heat as a heat source. However, since power output increases with increased input temperature, a heat source above ambient, if available, can advantageously be used to improve the performance of the device.

### 7.15 Substrate

Ideally the substrate onto which the semiconductor is fabricated should not cause any local disruption in the crystal structure of the semiconductor, which would result in variation in mobility within the bulk of the semiconductor. Furthermore, the substrate should be an insulator to prevent short-circuiting the device. The choice of material for the substrate is therefore important. For example, if the semiconductor is Indium Arsenide which has a lattice constant of 6.058A, a possible insulating substrate would be Indium Phosphide which has a lattice constant of 5.869A. The Indium Phosphide could be made to behave as a semi-insulator by doping it with iron or cobalt. The InP material can be fabricated using Metal Organic Chemical Vapor Deposition (MOCVD). For a donor concentration of less than 5×10¹⁶ per cm³, the iron doping yields semi-insulating material with a resistivity greater than 10⁷ ohm-cm [19]. When the device is constructed in a stack as shown in FIGS. 15-22 the semi-insulator substrate can serve as insulating material 44 between layers of semiconductor material 1.

### 7.16 Doping

The semiconductor must remain in depletion mode, to prevent the complete cancellation of the electric field by space charges. A region of the semiconductor without an E×B drift but loaded with carriers would short circuit the device, preventing its operation. The semiconductor can be left intrinsic. Doping can be beneficial as it increases the number of carriers, thereby improving the performance of the device, but to a point. Doping becomes detrimental when the carrier concentration becomes so high that the semiconductor layer ceases to be wholly in depletion mode, resulting in the cancellation of the electric field, and cessation of the E×B drift. In other words, maximum doping corresponds to the maximum carrier concentration expressed in equation (76). If doping is applied, it needs to be done judiciously to keep the semiconductor in depletion mode and out of starvation mode.

### 7.17 Applications

This technology can be used in applications such as heating, cooling, electrical energy production and lighting. Power supplies and coolers can be fabricated as integral subcomponents of semiconductor chips or modules.

### 8. Conclusion

This invention describes an E×B thermoelectric effect device optimized for maximum power output. Its performance was found to be highly sensitive to the thermodynamic threshold, the operating point where the asymmetry measure caused by the E×B drift is equal to the average path length. A device, properly tuned to this threshold, using ambient heat at 300K, operating at 250K, with a carrier density of 2562×10¹⁸ m⁻³, a magnetic field of 1.07T, an electric field of 325V/mm, and a thickness of 265 nm, can produce 1337 mW/mm² or 3967 times more energy than the best possible solar cell as defined by the Shockley-Queisser solar cell limit of 0.337 mW/mm². Far from this threshold, however, when operation approaches the thermodynamic limit, collisions truncate E×B cycloids into quasilinear segments, hinder the drift, and reduce the output power to an experimentally unmeasurable level.

Maximizing power by matching the resistance of a load to a source is well known. It can be stated in terms of equivalent resistivity as ρ_{Load}=ρ_{Drude}. This research extends this concept to systems with Hall resistivities. The power output of the E×B effect can also be maximized by matching the Hall resistivity ρ_{Hall} to the sum of the Drude resistivity ρ_{Drude} and the equivalent load resistivity ρ_{Loud}. (i.e., ρ_{Hall}=ρ_{Drude}+ρ_{Loud}).

The thermodynamic threshold was defined as the ratio r/λ where r is the size or measure of the asymmetry represented by the radius of a cyclotron orbit and λ is the average path length of carriers. It was found that power is maximized when r/λ=1. This equality is a powerful design optimization tool because both r and λ are functions of design parameters such as the magnetic field, the electric field, the dimensions of the device, and the concentration of particles. For example, the optimum relationship between magnetic field and mobility was found to be equal to 4. i.e., μ_{Bulk}B_{z}=4.

The E×B thermoelectric effect is driven by a field configuration, not by phonon drag or a temperature difference. It can convert ambient heat at room temperature to energy without the need for a temperature difference between a heat source and a heat sink. It can operate 24/7 regardless of climate.

While the above description contains many specificities, the reader should not construe these as limitations on the scope of the invention, but merely as exemplifications of preferred embodiments thereof. Those skilled in the art will envision many other possible variations within its scope. Accordingly, the reader is requested to determine the scope of the invention by the appended claims and their legal equivalents, and not by the examples which have been given.

### APPENDIX A

### Equations for Design Optimization

This appendix provides a set of equations selected from this paper for an optimized design. Every design parameter such as the fields B_{z}, and E_{y}, the dimensions δₓ and δ_{y}, the doping dependent carrier concentration n, and the power output are expressed solely in term of temperature T, mobility ABulk, permittivity & and carrier effective mass m. These material properties are usually temperature dependent.

One begins by assuming a material operating at temperature T. The next step is to evaluate the material properties at that temperature. This information is publicly available [16]. Finally, the material properties are inserted into the equations to obtain the optimal design parameters.

The optimal magnetic field is obtained from equation (53):

$${B}_{z} = \frac{4}{{μ}_{Bulk}} \qquad ( A1 )$$

The optimal semiconductor thickness is obtained from equation (59):

$${δ}_{y} = \frac{3}{\sqrt{10}} \frac{{μ}_{Bulk}}{q} \sqrt{2 {mk}_{B} T} \qquad ( A2 )$$

The optimal semiconductor length is obtained from equation (60:

$${δ}_{x} = \frac{3}{\sqrt{10}} \frac{{μ}_{Bulk}}{q} \sqrt{2 {mk}_{B} T} \qquad ( A3 )$$

The optimal electric field is obtained from equation (67):

$${E}_{y} = \frac{2 \sqrt{10}}{3} \frac{1}{{μ}_{Bulk}} \sqrt{\frac{2 {k}_{B} T}{m}} \qquad ( A4 )$$

The optimal carrier concentration is obtained from equation (75):

$$n = \frac{50}{9} \frac{ε}{m {μ}_{Bulk}^{2}} \qquad ( A5 )$$

The voltage across the device or the load is given by equation (69):

$${V}_{Load} = \frac{1}{q} {k}_{B} T \qquad ( A6 )$$

The maximum power output per unit volume is obtained from equation (79):

$$P = \frac{125}{81} \frac{q ε {k}_{B} T}{{m}^{2} {μ}_{Bulk}^{3}} \qquad ( A7 )$$

The maximum power per unit area is obtained from equation (80):

$$Power per unit area = \frac{125}{27 \sqrt{5}} \frac{ε}{{μ}_{Bulk}^{2}} {( \frac{{k}_{B} T}{m} )}^{3 / 2} \qquad ( A8 )$$

### APPENDIX B

### Drift Angle Calculation

The current density vector J is related to the field vector E by a resistivity matrix:

$$( \begin{matrix}{E}_{x} \\ {E}_{y}\end{matrix} ) = ( \begin{matrix}{ρ}_{Drude} + {ρ}_{Load} & + {ρ}_{Hall} \\ - {ρ}_{Hall} & {ρ}_{Drude} + {p}_{Load}\end{matrix} ) ( \begin{matrix}{J}_{x} \\ {J}_{y}\end{matrix} ) \qquad ( B1 )$$

where ρ_{Drude} is the Drude resistivity, ρ_{Load} is the load equivalent resistivity, and ρ_{Hall} is the Hall resistivity.

Solving for the current vector yields:

$$( \begin{matrix}{J}_{x} \\ {J}_{y}\end{matrix} ) = \frac{1}{{( {ρ}_{Drude} + {ρ}_{Load} )}^{2} + {ρ}_{Hall}^{2}} ( \begin{matrix}{ρ}_{Drude} + {ρ}_{Load} & - {ρ}_{Hall} \\ {ρ}_{Hall} & {ρ}_{Drude} + {ρ}_{Load}\end{matrix} ) ( \begin{matrix}{E}_{x} \\ {E}_{y}\end{matrix} ) \qquad ( B2 )$$

For Eₓ=0, the slope of the current vector is:

$$\frac{{J}_{y}}{{J}_{x}} = - \frac{{ρ}_{Drude} + {ρ}_{Load}}{{ρ}_{Hall}} \qquad ( B3 )$$

In this analysis, the slope angle θ_{E×B} is assumed to be down the potential energy gradient. Therefore, the sign in equation (B3) is inverted:

$$tan ( {θ}_{E \times B} ) = - \frac{{J}_{y}}{{J}_{x}} = \frac{{ρ}_{Drude} + {ρ}_{Load}}{{ρ}_{Hall}} \qquad ( B4 )$$

### REFERENCES

1. G. S. Levy, E×B Drift Thermoelectric Energy Generation Device; U.S. Pat. No. 10,971,669; Filed on 29 Aug. 2020. Awarded on 6 Apr. 2021.
2. G. S. Levy, An Overview of the E×B Thermoelectric Effect, MRS Advances, 2023 Springer, DOI 10.1557s43580-023-00521-5.
3. G. S. Levy, Reciprocal Hall Effect Energy Generation Device; US Patent 2018/0026555 Filed on Jun. 14, 2017.
4. Levy, G. S., Loschmidt's Paradox, Extended to CPT Symmetry, Bypasses Second Law, Journal of Applied Mathematics and Physics Vol. 7 No. 12, 20 Dec. 2019 DOI: 10.4236/jamp.2019.712221.
5. Skinner, B.; Fu, L.; Apparatus, systems, and methods for generating thermopower; U.S. Pat. No. 10,439,123.
6. Skinner, B.; Fu, L.; Large, nonsaturating thermopower in a quantizing magnetic field; arXiv.org>cond-mat>arXiv: 1706.06117.
7. Zhao, J., Ji. P . . . . Li. Y. et al. Ultrahigh-mobility semiconducting epitaxial graphene on silicon carbide. Nature 625, 60-65 (2024). https://doi.org/10.1038/s41586-023-06811-0
8. Boltzmann, Ludwig, Weitere Studien über das Wärmegleichgewicht unter Gasmolekülen, (Sitzungsberichte Akademie der Wissenschaften, 1872), 66; pp, 275-370. English translation: Boltzmann, L., Further Studies on the Thermal Equilibrium of Gas Molecules, The Kinetic Theory of Gases. History of Modern Physical Sciences (2003) 1. pp. 262-349.
9. Tolman, R. C., The Principle of Statistical Mechanics. Oxford at the Clarendon Press. (1938). Available online: https://archive.org/details/ThePrinciplesOfStatisticalMechanicsTolmanOxfordAtTheClarend onPress1938. (Accessed 5 Jun. 2016), page 138, equation 48.6.
10. Gibbs, J. W., Elementary Principles in Statistical Mechanics, Chapter XII, New York, Charles Scribner's Sons, 1902.
11. von Neumann, J., Proof of the Ergodic Theorem and the H-Theorem in Quantum Mechanics, May 10, 1929, Translator: Roderich Tumulka, arXiv: 1003.2133v2 [physics.hist-ph] 2 Sep. 2010.
12. Guiding Center, Wikipedia. Available online: https://en.wikipedia.org/wiki/Guiding_center. (Accessed on 19 Jan. 2022).
13. L. P. Freidberg, Plasma Physics and Fusion Energy, DOI: http://dx.doi.org/10.1017/CBO9780511755705; Publisher: Cambridge Books Online http://ebooks.cambridge.org.
14. Sheehan, D. P., and Gross, D. H. E., Extensivity and the thermodynamic limit: Why size really does matter. Physica A: Statistical Mechanics and its Applications 370(2):461-482. October 2006; also, on ResearchGate. Available online at https://www.researchgate.net/publication/223328200_Extensivity_and_the_thermodynamic_l imit_Why_size_really_does_matter. (Accessed on 13 Nov. 2019).
15. Feynman, Richard, The Feynman lecture on Physics, 43 Diffusion, Available online at https://www.feynmanlectures.caltech.edu/I_43.html (Accessed on 1 Jan. 2023).
16. New Semiconductor Materials. Characteristics and Properties, Electronic archive, Ioffe Physico-Technical Institute, available on the web at http://www.ioffe.ru/SVA/NSM/Semicond.
17. Solar Irradiance, NASA, https://www.nasa.gov/mission_pages/sdo/science/Solar % 20Irradiance.html (last accessed on 22 Apr. 2023).
18. Shockley Queisser Efficiency Limit, Wikipedia, html (last accessed on 26 Apr. 2023), https://en.wikipedia.org/wiki/Shockley % E2%80%93Queisser_limit.
19. Rumsby, D.; Ware, R.; Wittaker, M.; The Growth and Properties of Large Semi-Insulating Crystals of Indium Phosphide, Semi-Insulating III-V Materials, pp 59-67, G. J. Rees Editor, Nottingham, 1980.

I claim:

1. An E×B thermoelectric effect device utilizing the E×B drift to convert a heat input to an electrical energy output, said device comprising:
a) a forward channel having an orientation defining an X axis, having an upstream port and a downstream port; said forward channel further comprising:
i) a constituent material that holds electrical carriers, said constituent material having a bulk, surfaces, and a property of bulk carrier mobility selected to supports said E×B drift of said electrical carriers;
ii) an electric field source subjecting said forward channel to an electric field essentially perpendicular to its said X axis, said electric field having an orientation defining a Y axis; and
iii) a magnetic field source subjecting said forward channel to a magnetic field essentially perpendicular to said X and Y axes, said magnetic field having an orientation defining a Z axis;
b) said E×B drift producing a current of said electrical carriers through said forward channel from upstream port to downstream port;
c) said downstream port and said upstream port being electrically connected by a return channel comprising a load, thereby forming a closed electrical loop;
d) said E×B thermoelectric effect device having no thermal contact to any heat sink;
e) said E×B thermoelectric effect device having design parameters;
f) said carriers in said forward channel:
i) having an average path length being a function of said design parameters; and
ii) following cycloidal paths having an average size, called asymmetry measure, defined by a dimension of a cyclotron orbit of said carriers in said magnetic field, said asymmetry measure being a function of said design parameters;
g) said design parameters selected such that a ratio of said asymmetry measure to said average path length, called thermodynamic threshold, ranges between 0.1 and 10.

2. The E×B thermoelectric effect device of claim 1 wherein said design parameters are selected such that said average path length of said carriers is essentially equal to a combined equivalent mean free path, said combined equivalent mean free path being a harmonic sum of a bulk equivalent mean free path in said bulk, a surface equivalent mean free path at said surfaces, and a load equivalent mean free path in said load.

3. The E×B thermoelectric effect device of claim 1 wherein said design parameters are selected such that said average path length of said carriers is essentially equal to an isothermal scale height of said carriers caused by said electric field and a temperature of said forward channel.

4. The E×B thermoelectric effect device of claim 1 wherein said design parameters are selected such that said average path length of said carriers is essentially equal to a thickness of a depletion zone caused by said electric field, a doping, and a carrier concentration of said carriers in said forward channel.

5. The E×B thermoelectric effect device of claim 1 wherein a product of said forward channel bulk carrier mobility and said magnetic field is within a range between 1.0 and 10.

6. The E×B thermoelectric effect device of claim 1 wherein a product of said bulk carrier mobility and said magnetic field is within a range between 1.9 and 4.1.

7. The E×B thermoelectric effect device of claim 1 wherein:
a) said forward channel has a forward channel Drude resistance;
b) said load has a load Drude resistance; and
c) said forward channel Drude resistance and said load Drude resistance are essentially matched to each other.

8. The E×B thermoelectric effect device of claim 1 wherein:
a) said forward channel has a forward channel Hall resistance;
b) said forward channel has a forward channel Drude resistance;
c) said load has a load Drude resistance; and
d) said forward channel Hall resistance is essentially matched to a sum of said forward channel Drude resistance and said load Drude resistance.

9. The E×B thermoelectric effect device of claim 1 wherein said dimension of said cyclotron orbit is a radius of said cyclotron orbit.

10. The E×B thermoelectric effect device of claim 1 wherein said dimension of said cyclotron orbit is a diameter of said cyclotron orbit.

11. The E×B thermoelectric effect device of claim 1 wherein said ratio is further restricted to a range between 0.5 to 2.0.

12. The E×B thermoelectric effect device of claim 1 wherein said ratio is further restricted to a range between 0.9 to 1.1.

13. The E×B thermoelectric effect device of claim 1 wherein said forward channel holds said electrical carriers of at least one of two kinds:
a) a first kind being negatively charged, and making a negative contribution to said current; and
b) a second kind being positively charged, and making a positive contribution to said current; said forward channel having forward channel properties including said constituent material, and said bulk mobility, and additionally including a doping level, a concentration of said carriers, an effective mass of said positive carriers, and an effective mass of said negative carriers;
said forward channel properties selected to make said negative contributions and said positive contributions, unequal in magnitude resulting in said current being non-zero.

14. The E×B thermoelectric effect device of claim 1 wherein said semiconductor is InAs.

15. The E×B thermoelectric effect device of claim 1 wherein said semiconductor is InSb.

16. The E×B thermoelectric effect device of claim 1 wherein said semiconductor is InAsₓSb₁₋ₓ, proportion of As and Sb is selected in accordance with a temperature of operation.

17. The E×B thermoelectric effect device of claim 1 wherein said semiconductor is doped graphene.

18. The E×B thermoelectric effect device of claim 1 wherein said forward channel comprises a superconductor wherein said forward channel has a width along said Z axis smaller than a penetration depth of said magnetic field and has said thickness along said Y axis smaller than a penetration depth of said electric field.

19. The E×B thermoelectric effect device of claim 1 wherein said electric field source is comprised of capacitor plates charged by said electrical energy output.

20. The E×B thermoelectric effect device of claim 1 wherein:
a) said forward channel is called first forward channel, and has a first said orientation along its first said X axis and its first said electric field along its first said Y axis and its first said magnetic field along its first said Z axis;
b) said device also comprising at least one second forward channel having a second orientation along a second X axis, its second said electric field along a second said Y axis, and its second said magnetic field along a second said Z axis;
c) said first forward channels and said at least one second channel connected to contribute their said currents additively through said load.

21. The E×B thermoelectric effect device of claim 20 wherein said second electric field is parallel or antiparallel to said first electric field and said second magnetic field is parallel or antiparallel to said first electric field.

22. A method of fabricating an E×B thermoelectric effect device of claim 1 by selecting said design parameters which include a set of material properties of said forward channel constituent material, a temperature of said forward channel, said electric field, said magnetic field, a concentration of said carriers, a carrier mobility of said bulk, a dimensional separation of said surfaces, a load resistance, a doping; said method comprising:
a) expressing said asymmetry measure in terms of said design parameters;
b) expressing said average path length in terms of said design parameters;
c) equating said expressed asymmetry measure to said expressed average path length;
d) solving for said design parameters; and
e) fabricating said E×B thermoelectric effect device according to said solved design parameters.
